(19) United States
(12) Patent Application Publication
(10) Pub. No.: US 2026/0231648 A1
(43) Pub. Date: Aug. 6, 2026

(54) DISPLAY DEVICE, ELECTRONIC DEVICE AND METHOD FOR FABRICATING THE SAME

(71) Applicant: SAMSUNG DISPLAY CO., LTD., YONGIN-SI (KR)

(72) Inventors: Hyoung Sik KIM, Yongin-si (KR); Woo Jin CHO, Yongin-si (KR); Dong Jun KIM, Yongin-si (KR); Hee Sung YANG, Yongin-si (KR)

(21) Appl. No.: 19/316,126

(22) Filed: Sep. 2, 2025

(30) Foreign Application Priority Data
Feb. 6, 2025 (KR) 10-2025-0014973

(51) Int. Cl. H10K 59/80; H10K 59/12; H10K 59/122; H10K 59/123; H10K 71/60

(52) U.S. Cl. CPC H10K 59/80516; H10K 59/1201; H10K 59/122; H10K 59/123; H10K 71/60

(57) ABSTRACT

A display device includes a substrate including a light emitting area and a non-light emitting area, overlapping the light emitting area, and including a connection electrode. A bank structure is disposed on the connection electrode and includes an overhang structure. A first anode contact hole penetrates through the bank structure. An anode auxiliary electrode overlaps the first anode contact hole and is in contact with the connection electrode. An anode electrode is disposed on the anode auxiliary electrode. An anode planarization layer overlaps the first anode contact hole, disposed between the anode auxiliary electrode and the anode electrode, and including an inorganic material. A second anode contact hole overlaps the non-light emitting area, penetrating through a portion of the anode planarization layer, and spaced apart from the first anode contact hole.

### CROSS-REFERENCE TO RELATED APPLICATION

This application claims priority under 35 U.S.C. § 119 to Korean Patent Application No. 10-2025-0014973, filed on Feb. 6, 2025 in the Korean Intellectual Property Office, the contents of which in its entirety are herein incorporated by reference.

### TECHNICAL FIELD

The present disclosure relates to display technology and, more specifically, to a display device, an electronic device using the same, and a method for fabricating the display device.

### DISCUSSION OF THE RELATED ART

As the information society develops, display panels are being used in a wider variety of electronic devices. For example, display panels have been applied to various electronic devices such as smartphones, digital cameras, laptop/notebook computers, navigation devices, and smart televisions. The display panel may be a flat panel display device such as a liquid crystal display (LCD) device, a field emission display device, or an organic light emitting diode (OLED) display device. OLED display devices, and other such light emitting display devices, may include pixels that are capable of emitting light by themselves, thereby displaying an image without a backlight unit providing the light to the display panel.

Recently, display panels are designed to provide an increased pixel density so as to produce a higher quality image. For example, the display device may have a pixel density of 1500 pixels per inch (PPI) or more.

### SUMMARY

A display device includes a substrate and a connection electrode. The substrate includes a light emitting area and a non-light emitting area, overlapping the light emitting area. A bank structure is disposed on the connection electrode and includes an overhang structure. A first anode contact hole penetrates through the bank structure. An anode auxiliary electrode overlaps the first anode contact hole and is in contact with the connection electrode. An anode electrode is disposed on the anode auxiliary electrode. An anode planarization layer overlaps the first anode contact hole, is disposed between the anode auxiliary electrode and the anode electrode, and includes an inorganic material. A second anode contact hole overlaps the non-light emitting area, penetrates through a portion of the anode planarization layer, and is spaced apart from the first anode contact hole.

In a portion overlapping the first anode contact hole, the anode electrode may be in contact with the anode planarization layer, and may be spaced apart from the anode auxiliary electrode, and in a portion overlapping the second anode contact hole, the anode electrode may be in contact with the anode auxiliary electrode.

The anode electrode may be connected to the connection electrode through the anode auxiliary electrode.

The anode planarization layer may planarize a step difference formed by the anode auxiliary electrode in the portion overlapping the first anode contact hole.

The display device may further include an element insulating layer covering an edge of the anode electrode and defining a light emitting opening. The first anode contact hole may overlaps the light emitting opening, and the second anode contact hole might not overlap the light emitting opening.

The display may further include an insulating pattern that is spaced apart from the anode planarization layer by the second anode contact hole. The insulating pattern may include a same material as the anode planarization layer.

The display may further include a light emitting layer disposed in contact with the anode electrode in a portion overlapping the light emitting opening. A cathode electrode may be disposed on the light emitting layer and may be in contact with the bank structure. The light emitting layer may be in contact with the element insulating layer and the insulating pattern.

The anode auxiliary electrode may include a first portion in contact with the anode planarization layer, a second portion in contact with the insulating pattern, and a third portion in contact with the anode electrode. The third portion may be disposed between the first portion and the second portion.

The bank structure may include a first bank layer. A second bank layer may be disposed on the first bank layer. A third bank layer may have a tip that protrudes further toward the non-light emitting area than a first side surface of the second bank layer. The anode planarization layer overlapping the first anode contact hole may penetrate through the first bank layer, the second bank layer, and the third bank layer.

In a plan view, the first anode contact hole and the second anode contact hole may be spaced apart from each other, and in the plan view, the anode electrode may entirely cover the first anode contact hole and the second anode contact hole.

A method for fabricating a display device includes forming an anode planarization layer after forming a first anode contact hole penetrating through a bank structure. An anode electrode is formed after forming a second anode contact hole penetrating through the anode planarization layer. An overhang structure of the bank structure is formed by performing an etching process. A light emitting layer, a cathode electrode, and an element inorganic layer are formed on the anode electrode.

In the forming of the anode planarization layer after forming the first anode contact hole penetrating through the bank structure, a portion of the anode planarization layer may be removed by a chemical mechanical planarization (CMP) process.

In the forming of the anode electrode after forming the second anode contact hole penetrating through the anode planarization layer, the second anode contact hole may be formed by performing a dry etching process.

In the forming of the overhang structure of the bank structure by performing the etching process, the bank structure may include a first bank layer, a second bank layer, and a third bank layer, and the second bank layer and the third bank layer may include different metal materials from each other.

In the forming of the light emitting layer, the cathode electrode, and the element inorganic layer on the anode electrode, the light emitting layer, the cathode electrode, and the element inorganic layer may be formed by a photo pattern process.

An electronic device includes at least one display device including a substrate including a light emitting area and a non-light emitting area, overlapping the light emitting area, and including a connection electrode. At least one of a display module, a processor, a memory, and a power module is connected to the display device. The at least one display device includes a bank structure disposed on the connection electrode and including an overhang structure. A first anode contact hole penetrates through the bank structure. An anode auxiliary electrode overlaps the first anode contact hole and is in contact with the connection electrode. An anode electrode is disposed on the anode auxiliary electrode. An anode planarization layer overlaps the first anode contact hole, is disposed between the anode auxiliary electrode and the anode electrode, and includes an inorganic material. A second anode contact hole overlaps the non-light emitting area, penetrates through a portion of the anode planarization layer, and is spaced apart from the first anode contact hole.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a cross-sectional view illustrating the display device according to an embodiment;

FIG. 3 is a plan view illustrating a display layer of the display device according to an embodiment;

FIG. 4 is a layout diagram illustrating an arrangement of a plurality of pixels disposed in a display area of FIG. 3;

FIG. 5 is a cross-sectional view illustrating an example of the display layer taken along line A1-A1′ of FIG. 4;

FIG. 6 is an enlarged cross-sectional view of a display element layer overlapping a first light emitting area in FIG. 5;

FIG. 7 is an enlarged cross-sectional view of area ‘A’ in FIG. 6;

FIG. 8 is an enlarged plan view of an anode electrode overlapping a first anode contact hole and a second anode contact hole in FIG. 6;

FIG. 9 is a flowchart illustrating a method for fabricating the display element layer of FIG. 5;

FIGS. 10, 11, 12, and 13 are cross-sectional views illustrating step S100 of FIG. 9;

FIGS. 14, 15, and 16 are cross-sectional views illustrating step S200 of FIG. 9;

FIGS. 17, 18, and 19 are cross-sectional views illustrating step S300 of FIG. 9;

FIGS. 20, 21, 22, and 23 are cross-sectional views illustrating step S400 of FIG. 9;

FIG. 24 is a block diagram of an electronic device according to an embodiment; and

FIG. 25 is a schematic diagram of electronic devices according to various embodiments.

### DETAILED DESCRIPTION OF THE EMBODIMENTS

Aspects and features of the present disclosure and methods of accomplishing the same may be understood more readily by reference to the following detailed description of embodiments and the accompanying drawings. The present disclosure may, however, be embodied in many different forms and should not necessarily be construed as being limited to the embodiments set forth herein. Rather, these embodiments are provided so that this disclosure will be thorough and complete and will fully convey the concept of the present disclosure to those skilled in the art.

It will be understood that when an element or layer is referred to as being “on” another element or layer, the element or layer can be directly on another element or layer or intervening elements or layers. Like reference numerals may refer to like elements throughout the specification and the drawings. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

It will be understood that, although the terms first, second, third, etc., may be used herein to describe various elements, these elements should not necessarily be limited by these terms. These terms are used to distinguish one element from another element. Thus, a first element discussed below could be termed a second element without departing from the teachings of the present disclosure.

Features of various embodiments of the present disclosure may be partially or entirely coupled to or combined with each other, and may be inter-operated and driven in technically various ways. The embodiments may be implemented independently from each other, or may be implemented together in a co-dependent relationship.

Embodiments of the present disclosure relate to a high-resolution display device, particularly an organic light emitting display panel, designed to overcome challenges associated with step differences and defects in thin-film layers. The display comprises a substrate defining both light-emitting and non-light-emitting areas, upon which a bank structure with a multi-layered overhang design is formed. A first anode contact hole penetrates the bank structure and allows connection between a lower connection electrode and an anode auxiliary electrode, which in turn interfaces with an anode electrode. To resolve step height variations and potential damage to transparent conductive oxides during manufacturing, the design introduces an inorganic anode planarization layer that levels the step differences above the first anode contact hole, ensuring a smoother surface for subsequent layers and preventing defects such as outgassing or material damage.

This planarization layer not only flattens irregularities but also serves as an insulating barrier, enabling the formation of a second anode contact hole in the non-light-emitting region, spaced apart from the first. This structural distinction allows electrical connection where necessary while maintaining insulation in regions where light emission integrity is critical. The anode electrode is thereby connected differently in light-emitting and non-light-emitting zones, ensuring uniformity of the anode's thickness and eliminating issues like uneven deposition of the light-emitting layers, which are desirable for consistent pixel performance in high pixel per inch (PPI) displays. The bank structure itself, including layered metals with varying etch resistances, creates precise boundaries for light emission without requiring a fine metal mask, simplifying the fabrication process.

The method of manufacturing the display device involves forming the first contact hole through the bank structure, depositing the anode auxiliary electrode and the planarization layer, then creating the second contact hole through selective etching, followed by forming the anode electrode and depositing the light-emitting and cathode layers. The unique overhang design of the bank structure, combined with precise etching and layering techniques, facilitates high-density pixel arrangements while maintaining mechanical and electrical integrity. Thus, reliability concerns in high-resolution displays may be addressed by ensuring flatness and structural robustness in regions used for electrical connections and light emission, enabling its integration into various electronic devices like smartphones, wearables, and advanced displays requiring fine pixel pitches.

Hereinafter, specific embodiments will be described with reference to the accompanying drawings.

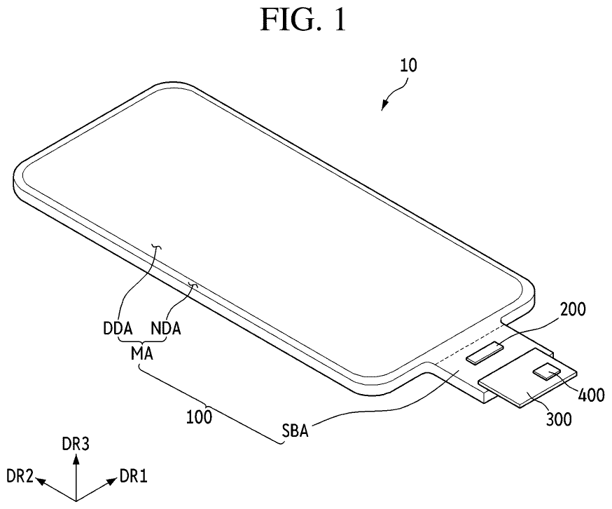

FIG. 1 is a perspective view illustrating a display device according to an embodiment.

Referring to FIG. 1, a display device 10 may be applied to portable electronic devices such as a mobile phone, a smartphone, a tablet computer, a mobile communication terminal, an electronic notebook, an electronic book, a portable multimedia player (PMP), a navigation device, and an ultra mobile personal computer (UMPC). For example, the display device 10 may be applied to a display unit of a television, a laptop/notebook computer, a computer monitor, a digital billboard, or an Internet of Things (IoT) device. As an example, the display device 10 may be applied to a wearable device such as a smart watch, a watch phone, a glasses-type display, and a head mounted display (HMD).

The display device 10 may be formed in a planar shape similar to a quadrilateral. For example, the display device 10 may have a planar shape similar to a quadrilateral having a pair of short sides extending in a first direction DR1 and a pair of long sides extending in a second direction DR2. A corner where the short side in the first direction DR1 and the long side in the second direction DR2 meet may be rounded to have a predetermined curvature or may be formed at a right angle. The planar shape of the display device 10 is not necessarily limited to the quadrilateral, and may be formed similarly to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DDA including pixels displaying an image, and a non-display area NDA disposed around the display area DDA.

The display area DDA may emit light from a plurality of light emitting areas or a plurality of openings to be described later. For example, the display panel 100 may include a pixel circuit including switching elements, an element insulating layer defining the light emitting areas or the openings, and a self-light emitting element. For example, the self-light emitting element may include, but is not necessarily limited to, at least one of an organic light emitting diode (LED) including an organic light emitting layer, a quantum dot LED including a quantum dot light emitting layer, an inorganic LED including an inorganic semiconductor, and a micro LED. In the following drawings, it is illustrated that the self-light emitting element is an organic light emitting diode.

The non-display area NDA may be an area outside the display area DDA. The non-display area NDA may be defined as an edge area of the main area MA of the display panel 100.

The sub-area SBA may be an area extending from one side of the main area MA. The sub-area SBA may include a flexible material that may be bent, folded, rolled, or the like, to at least a noticeable extent without cracking or otherwise sustaining damage thereto. For example, when the sub-area SBA is bent, the sub-area SBA may overlap the main area MA in a thickness direction (e.g., a third direction DR3). The sub-area SBA may include the display driver 200 and a pad portion connected to the circuit board 300. In an embodiment, the sub-area SBA may be omitted, and the display driver 200 and the pad portion may be disposed in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the sub-area SBA. As an example, the display driver 200 may be mounted on the circuit board 300.

The circuit board 300 may be attached onto the pad portion of the display panel 100 using an anisotropic conductive film (ACF). The circuit board 300 may be a flexible film such as a flexible printed circuit board, a printed circuit board, or a chip on film.

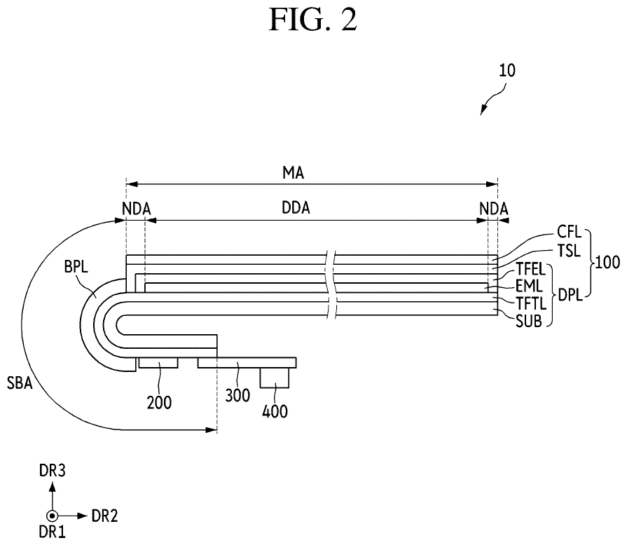

The touch driver 400 may be mounted on the circuit board 300. The touch driver 400 may be connected to a touch sensor layer (‘TSL’ in FIG. 2) for sensing and driving a touch.

Thus, embodiments of the present disclosure relate to a versatile display device suitable for various electronics, featuring a planar display panel with both light-emitting and non-display areas, and optionally a flexible sub-area housing the display driver and connections. It may integrate components like a display driver, circuit board, and touch driver to support high-resolution self-emissive technologies such as OLEDs, quantum dot LEDs, and micro-LEDs.

FIG. 2 is a cross-sectional view illustrating the display device according to an embodiment.

Referring to FIG. 2, the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate. The substrate SUB may be a flexible substrate that may be bent, folded, rolled, or the like to at least a noticeable extent without being damaged. For example, the substrate SUB may include a polymer resin such as polyimide PI, but is not necessarily limited thereto. In an embodiment, the substrate SUB may include a glass material or a metal material.

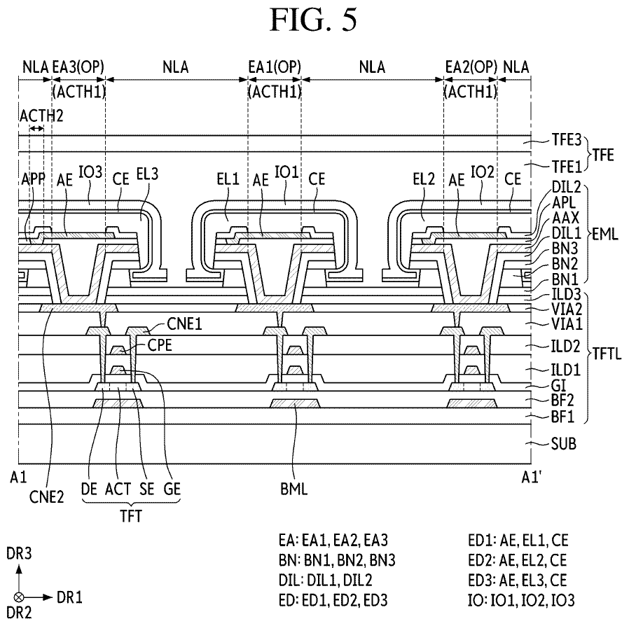

The transistor layer TFTL may be disposed on the substrate SUB. The transistor layer TFTL may be disposed in a portion overlapping the display area DDA, the non-display area NDA, and the sub-area SBA. The transistor layer TFTL may include a plurality of transistors (‘TFT’ in FIG. 5).

The display element layer EML may be disposed on the transistor layer TFTL. The display element layer EML may be disposed in a portion overlapping the display area DDA. The display element layer EML may include, but is not necessarily limited to including, at least one of an organic light emitting diode (LED) including an organic light emitting layer, a quantum dot LED including a quantum dot light emitting layer, an inorganic LED including an inorganic semiconductor, and a micro LED.

The thin film encapsulation layer TFEL may be disposed on the display element layer EML. The thin film encapsulation layer TFEL may be disposed in a portion overlapping the display area DDA and the non-display area NDA. The thin film encapsulation layer TFEL may cover upper and side surfaces of the display element layer EML, and may protect the display element layer EML from oxygen and moisture from the outside. The thin film encapsulation layer TFEL may include at least one inorganic film and at least one organic film for encapsulating the display element layer EML. In some embodiments, the thin film encapsulation layer TFEL may be omitted.

The touch sensor layer TSL may be disposed on the thin film encapsulation layer TFEL. The touch sensor layer TSL may be disposed in a portion overlapping the display area DDA and the non-display area NDA. The touch sensor layer TSL may sense a user's touch in a mutual capacitance method or a self-capacitance method. In some embodiments, the touch sensor layer TSL may be omitted.

The color filter layer CFL may be disposed on the touch sensor layer TSL. The color filter layer CFL may be disposed in a portion overlapping the display area DDA and the non-display area NDA. The color filter layer CFL may absorb a portion of ambient to reduce reflected light caused thereby. Therefore, the color filter layer CFL may prevent color distortion caused by reflection of external light.

As the color filter layer CFL is directly disposed on the touch sensor layer TSL, the display device 10 might not require a separate substrate for the color filter layer CFL. Therefore, the display device 10 may have a relatively small thickness. In some embodiments, the color filter layer CFL may also be omitted.

As illustrated in FIG. 2, a portion of the display panel 100 overlapping the sub-area SBA may be bent. When a portion of the display panel 100 is bent, the display driver 200, circuit board 300, and the touch driver 400 may overlap the main area MA in the third direction DR3.

When a portion of the display panel 100 is bent, a bending protection layer BPL may protect a lower structure overlapping the sub-area SBA from bending stress.

Thus, the display device may include such layers as a substrate, transistor layer, display element layer, thin film encapsulation, touch sensor layer, and optional color filter, all stacked to enable flexible and compact designs. This multilayer arrangement may protect the display from moisture and oxygen while allowing touch functionality and high-quality image display.

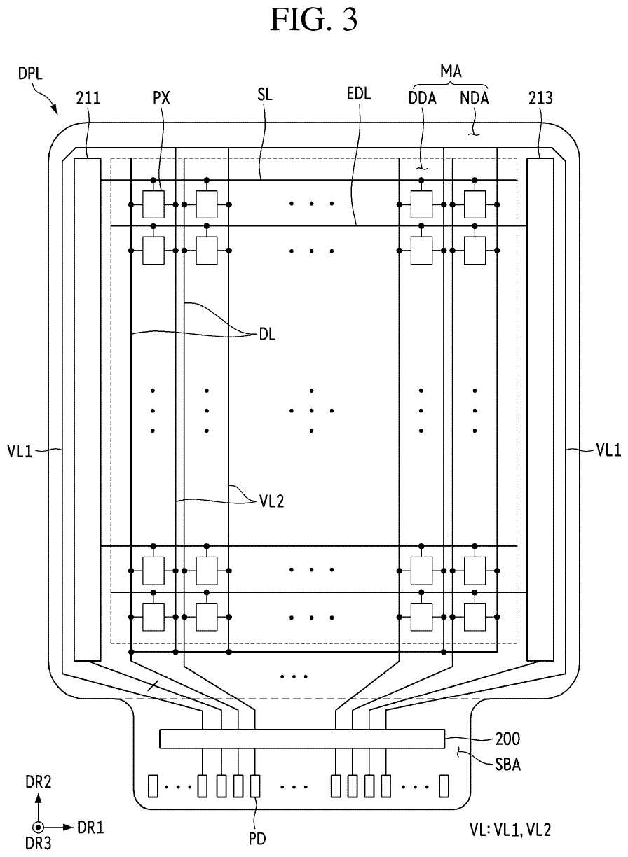

FIG. 3 is a plan view illustrating a display layer of the display device according to an embodiment.

Referring to FIG. 3, the display layer DPL may include a plurality of pixels PX in a portion overlapping the display area DDA, and a plurality of power lines VL, a plurality of scan lines SL, a plurality of emission control lines EDL, and a plurality of data lines DL that are connected to the plurality of pixels PX.

The plurality of scan lines SL may each extend in the first direction DR1 and may be spaced apart from each other in the second direction DR2 intersecting the first direction DR1. The scan lines SL may be arranged along the second direction DR2. The scan lines SL may sequentially supply a scan signal to the plurality of pixels PX.

The emission control lines EDL may each extend in the first direction DR1 and may be spaced apart from each other in the second direction DR2. The emission control lines EDL may be arranged along the second direction DR2. The emission control lines EDL may sequentially supply a light emitting signal to the plurality of pixels PX.

The data lines DL may extend in the second direction DR2 and may be spaced apart from each other in the first direction DR1. The data lines DL may be arranged along the first direction DR1. The data lines DL may supply a data voltage to the plurality of pixels PX. The data voltage may determine luminance of each of the plurality of pixels PX.

The power line VL may include a main power line VL1 and a sub-power line VL2. At least one of a first power voltage (high potential voltage) or a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA at least on two sides thereof. The non-display area NDA may include a scan driver 211 and an emission control driver 213.

The scan driver 211 may be disposed on the outside of one side of the display area DDA or on one side of the non-display area NDA. The scan driver 211 may include a plurality of driving transistors that generate gate signals based on a gate control signal.

The emission control driver 213 may be disposed on the outside of the other side of the display area DDA or on the other side of the non-display area NDA. The emission control driver 213 may include a plurality of emission control transistors that generate light emitting signals based on an emission control signal.

The display layer DPL included in an embodiment may include a display driver 200 and a plurality of pad electrodes PD in a portion overlapping the sub-area SBA. The plurality of pad electrodes PD may be spaced apart from each other in the first direction DR1, and each pad electrode PD may be connected to each different line.

Thus, multiple pixels may be interconnected by scan lines, emission control lines, data lines, and power lines arranged in specific directions to manage signals, voltages, and luminance across the panel. The non-display area may house drivers like the scan driver and emission control driver, while the sub-area may include a display driver and pad electrodes connecting to various lines for organized electrical routing.

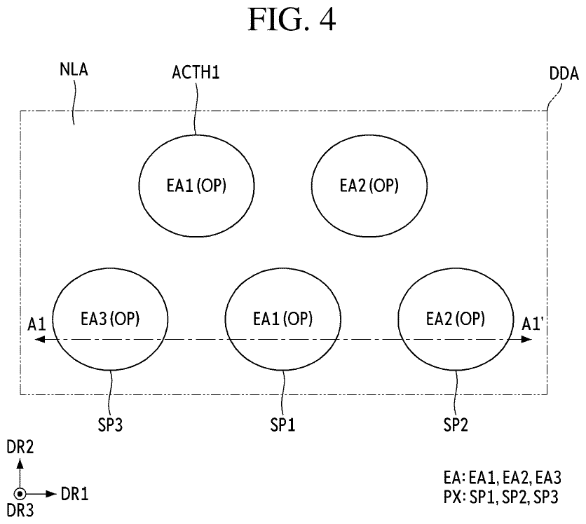

FIG. 4 is a layout diagram illustrating an arrangement of a plurality of pixels disposed in a display area of FIG. 3.

Referring to FIG. 4, a pixel PX, according to an embodiment, may include a first sub-pixel SP1, a second sub-pixel SP2, and a third sub-pixel SP3 disposed in a portion overlapping the display area DDA. The first sub-pixel SP1, the second sub-pixel SP2, and the third sub-pixel SP3 may be spaced apart from each other.

The pixel PX may include a light emitting area EA. The light emitting area EA may be a portion from which light is emitted. As an example, the first sub-pixel SP1 may include a first light emitting area EA1, the second sub-pixel SP2 may include a second light emitting area EA2, and the third sub-pixel SP3 may include a third light emitting area EA3.

In an embodiment, the first light emitting area EA1, the second light emitting area EA2, and third light emitting area EA3 may emit light of different colors. As an example, the first light emitting area EA1 may emit red light, the second light emitting area EA2 may emit green light, and the third light emitting area EA3 may emit blue light. However, the first light emitting area EA1, the second light emitting area EA2, and the third light emitting area EA3 are not necessarily limited thereto, and may also emit the same color depending on the embodiment.

In an embodiment, the light emitting area EA may be defined by a light emitting opening OP. The light emitting opening OP may be defined by a second element insulating layer (‘DIL2’ in FIG. 5) described later.

In a plan view, a first anode contact hole ACTH1 may be disposed in a portion overlapping the light emitting area EA and the light emitting opening OP. A detailed structure of the first anode contact hole ACTH1 will be described later.

The display device 10, according to an embodiment, may include a non-light emitting area NLA in a portion overlapping the display area DDA. The non-light emitting area NLA may prevent color mixing of light emitted from the first light emitting area EA1, the second light emitting area EA2, and the third light emitting area EA3.

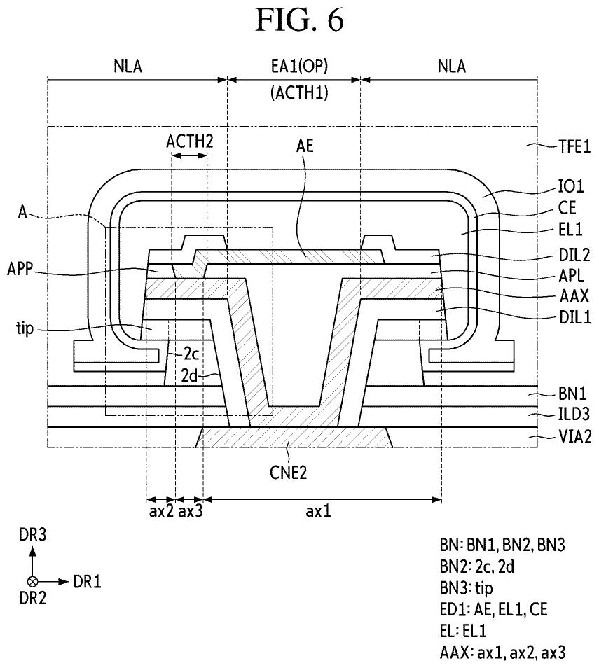

FIG. 5 is a cross-sectional view illustrating an example of the display layer taken along line A1-A1′ of FIG. 4 and FIG. 6 is an enlarged cross-sectional view of a display element layer overlapping a first light emitting area in FIG. 5. FIG. 5 illustrates a cross-sectional structure of the first sub-pixel SP1, the second sub-pixel SP2, and the third sub-pixel SP3 in a portion overlapping the display area DDA of the display device 10.

Referring to FIGS. 5 and 6, a transistor layer TFTL may be disposed on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be disposed on the substrate SUB. The first buffer layer BF1 may include an inorganic film capable of preventing permeation of air or moisture. For example, the first buffer layer BF1 may include a plurality of inorganic films alternately stacked.

The lower metal layer BML may be disposed on the first buffer layer BF1. The lower metal layer BML may include an electrically conductive metal and may be formed as, for example, a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. For example, the second buffer layer BF2 may include a plurality of inorganic films alternately stacked.

The transistor TFT may be disposed on the second buffer layer BF2, and may constitute a pixel circuit. As an example, the transistor TFT may be a driving transistor or a switching transistor of the pixel circuit.

The transistor TFT may include an active layer ACT, a source electrode SE, a drain electrode DE, and a gate electrode GE.

The active layer ACT may be disposed on the second buffer layer BF2. The active layer ACT may overlap the gate electrode GE in the third direction DR3 and may be insulated from the gate electrode GE by the gate insulating layer GI. The drain electrode DE and the source electrode SE may be portions formed by conducting a portion of the active layer ACT.

The gate insulating layer GI may be disposed on the active layer ACT. The gate insulating layer GI may cover the active layer ACT and the second buffer layer BF2, and may insulate the active layer ACT and the gate electrode GE from each other. The gate insulating layer GI may include a contact hole through which the first connection electrode CNE1 penetrates.

The gate electrode GE may be disposed on the gate insulating layer GI. The gate insulating layer GI may be disposed between the gate electrode GE and the active layer ACT.

The gate electrode GE may include a conductive metal and may be formed as, for example, a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first insulating layer ILD1 may cover the gate electrode GE and the gate insulating layer GI. The first insulating layer ILD1 may include a contact hole through which the first connection electrode CNE1 penetrates. The contact hole of the first insulating layer ILD1 may be connected to the contact hole of the gate insulating layer GI and a contact hole of the second insulating layer ILD2.

The capacitor electrode CPE may be disposed on the first insulating layer ILD1. The capacitor electrode CPE may overlap the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may include a contact hole through which the first connection electrode CNE1 penetrates. The contact hole of the second insulating layer ILD2 may be connected to the contact hole of the first insulating layer ILD1 and the contact hole of the gate insulating layer GI.

The first connection electrode CNE1 may be disposed on the second insulating layer ILD2. The first connection electrode CNE1 may electrically connect the drain electrode DE of the transistor TFT and the second connection electrode CNE2 to each other. The first connection electrode CNE1 may be inserted into the contact holes formed in the first insulating layer ILD1, the second insulating layer ILD2, and the gate insulating layer GI and be in contact with the drain electrode DE of the transistor TFT.

The first via layer VIA1 may be disposed on the first connection electrode CNE1 and the second insulating layer ILD2. The first via layer VIA1 may planarize a lower structure. The first via layer VIA1 may include a contact hole through which the second connection electrode CNE2 penetrates.

The first via layer VIA1 may include an organic insulating material. As an example, the first via layer VIA1 may include an acrylic resin, polyimide, polyamide, benzocyclobutene, a phenol resin, etc.

The second connection electrode CNE2 may be disposed on the first via layer VIA1. The second connection electrode CNE2 may be disposed in a portion overlapping the light emitting area EA. The second connection electrode CNE2 may be inserted into the contact hole formed in the first via layer VIA1 and be in contact with the first connection electrode CNE1. In the present specification, the second connection electrode CNE2 may be referred to as a connection electrode, a conductive layer, or a conductive pattern.

The second via layer VIA2 may be disposed on the first via layer VIA1. The second via layer VIA2 may planarize a step formed by the second connection electrode CNE2.

The second via layer VIA2 may include an organic material. As an example, the second via layer VIA2 may include an acrylic resin, a silicone resin, a silicone acrylic resin, an epoxy resin, polyimide, polyamide, benzocyclobutene, a phenol resin, etc.

The third insulating layer ILD3 may be disposed on the second via layer VIA2. The third insulating layer ILD3 may assist in preventing outgas caused by the organic material of the second via layer VIA2 from permeating into the display element layer EML.

The third insulating layer ILD3 may include an inorganic insulating material. As an example, the third insulating layer ILD3 may include at least one of silicon nitride, silicon oxide, and silicon oxynitride.

The first anode contact hole ACTH1 may be disposed in a portion overlapping the light emitting area EA. In the portion overlapping the first anode contact hole ACTH1, the second connection electrode CNE2 may be exposed. In the portion overlapping the first anode contact hole ACTH1, the second connection electrode CNE2 may be connected to the anode electrode AE.

The display element layer EML may be disposed on the transistor layer TFTL. The display element layer EML may include a bank structure BN, an element insulating layer DIL, an anode auxiliary electrode AAX, an anode planarization layer APL, a light emitting element ED, an insulating pattern APP, and an element inorganic layer IO.

In an embodiment, the first anode contact hole ACTH1 may be disposed in a portion overlapping the light emitting area EA and the light emitting opening OP. The first anode contact hole ACTH1 may penetrate through the third insulating layer ILD3 and the bank structure BN.

The bank structure BN may be disposed on the third insulating layer ILD3. The bank structure BN may be disposed in the portions overlapping the light emitting area EA and the non-light emitting area NLA.

The bank structure BN may assist in positioning the first to third light emitting elements ED1, ED2, and ED3 in the portions overlapping the first to third light emitting areas EA1, EA2, and EA3, respectively, and may assist in electrically connecting the cathode electrodes CE spaced apart from each other in the first to third light emitting areas EA1, EA2, and EA3.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be disposed on the third insulating layer ILD3. The first bank layer BN1 may cover the third insulating layer ILD3 in a portion overlapping the light emitting area EA and the non-light emitting area NLA.

The first bank layer BN1 may assist in applying a low potential voltage to the cathode electrode CE. The first bank layer BN1 may include a conductive metal having etching resistance. As an example, the first bank layer BN1 may include titanium (Ti).

The first bank layer BN1 may be penetrated by the first anode contact hole ACTH1 in a portion overlapping the light emitting area EA. For example, the first bank layer BN1 may surround the first anode contact hole ACTH1 and may be formed in the form of one conductive pattern to surround the first anode contact hole ACTH1.

The second bank layer BN2 may be in contact with the first bank layer BN1. The second bank layer BN2 may be penetrated by the first anode contact hole ACTH1 in a portion overlapping the light emitting area EA. For example, the second bank layer BN2 may surround the first anode contact hole ACTH1.

A plurality of second bank layers BN2 may be formed and may be spaced apart from each other. For example, the plurality of second bank layers BN2 may be spaced apart from each other in the portions overlapping the first to third light emitting areas EA1, EA2, and EA3, respectively. The second bank layer BN2 may be an island-shaped conductive pattern.

The second bank layer BN2 may assist in electrically connecting the first bank layer BN1 and the third bank layer BN3. For example, the second bank layer BN2 may be electrically connected to the first bank layer BN1 and the third bank layer BN3. Accordingly, the second bank layer BN2 disposed in the portion overlapping the first light emitting area EA1, the second bank layer BN2 disposed in the portion overlapping the second light emitting area EA2, and the second bank layer BN2 disposed in the portion overlapping the third light emitting area EA3 may be electrically connected by the first bank layer BN1.

The second bank layer BN2 may include a metal with high electrical conductivity. As an example, the second bank layer BN2 may include aluminum (Al).

The third bank layer BN3 may be in contact with the second bank layer BN2. The third bank layer BN3 may be penetrated by the first anode contact hole ACTH1 in a portion overlapping the light emitting area EA. For example, the third bank layer BN3 may surround the first anode contact hole ACTH1.

A plurality of third bank layers BN3 may be formed and may be spaced apart from each other in the first direction DR1. For example, the plurality of third bank layers BN3 may be spaced apart from each other in the portions overlapping the first to third light emitting areas EA1, EA2, and EA3, respectively. The third bank layer BN3 may be an island-shaped conductive pattern.

The third bank layer BN3 may include a conductive metal having etching resistance. As an example, the third bank layer BN3 may include titanium (Ti).

In an embodiment, the third bank layer BN3 disposed in the portion overlapping the first light emitting area EA1, the third bank layer BN3 disposed in the portion overlapping the second light emitting area EA2, and the third bank layer BN3 disposed in the portion overlapping the third light emitting area EA3 may be electrically connected through the second bank layer BN2 and the first bank layer BN1. To the extent that an element is not described in detail with respect to this figure, it may be understood that the element is at least similar to a corresponding element that has been described elsewhere within the present disclosure.

As illustrated in FIGS. 5 and 6, the second bank layer BN2 may include a first side surface 2c facing the non-light emitting area NLA, and the third bank layer BN3 may include a tip that protrudes further in the first direction DR1 than the first side surface 2c of the second bank layer BN2. Accordingly, the first side surface 2c of the second bank layer BN2 and the tip of the third bank layer BN3 may form an undercut, and thus the bank structure BN may have an overhang structure.

The display device 10, according to an embodiment, may include a first light emitting element ED1, a second light emitting element ED2, and a third light emitting element ED3 spaced apart from each other without a separate fine metal mask in the fabricating process, as the bank structure BN includes the tip. The fabricating process will be described later.

The element insulating layer DIL may include a first element insulating layer DIL1 and a second element insulating layer DIL2.

The first element insulating layer DIL1 may be disposed on the third bank layer BN3. The first element insulating layer DIL1 may cover the third bank layer BN3 and may overlap the tip of the third bank layer BN3 in the third direction DR3.

The first element insulating layer DIL1 may be penetrated by the first anode contact hole ACTH1 in a portion overlapping the light emitting area EA. Accordingly, the first element insulating layer DIL1 may include an opening. For example, the first element insulating layer DIL1 may expose the second connection electrode CNE2 in a portion that overlaps the opening defined by the first element insulating layer DIL1.

The first element insulating layer DIL1 may separate and insulate the bank structure BN and the anode electrode AE from each other so that the bank structure BN and the anode electrode AE are not in contact with each other. Accordingly, the first element insulating layer DIL1 may entirely cover a side surface of the bank structure BN facing the first anode contact hole ACTH1. Therefore, the first element insulating layer DIL1 may solve a short circuit defect of the display device 10 caused by the contact between the anode electrode AE and the bank structure BN.

The first element insulating layer DIL1 may include an inorganic insulating material. As an example, the first element insulating layer DIL1 may include at least one of silicon nitride, silicon oxide, and silicon oxynitride.

The anode auxiliary electrode AAX may be disposed on the first element insulating layer DIL1. The anode auxiliary electrode AAX may be in contact with and cover the first element insulating layer DIL1 and may extend therefrom to be in contact with the second connection electrode CNE2. The anode auxiliary electrode AAX may be electrically connected to the second connection electrode CNE2.

The anode auxiliary electrode AAX may cover the side surface of the bank structure BN facing the first anode contact hole ACTH1.

The anode auxiliary electrode AAX may cover the bank structure BN and the first element insulating layer DIL1 with a uniform thickness along a profile formed by the bank structure BN and the first element insulating layer DIL1. Accordingly, in a portion overlapping the first anode contact hole ACTH1, the anode auxiliary electrode AAX may include a step difference identical to a shape of the lower structure. The meaning of uniform thickness, as described herein, may include a process error of 10% or less, e.g., a thickness that is consistent within +/−10%.

The anode auxiliary electrode AAX may include a transparent conductive material (TCO). As an example, the anode auxiliary electrode AAX may include at least one of indium-zinc-oxide (IZO) and indium-tin-oxide (ITO).

The anode auxiliary electrode AAX may assist in electrically connecting the anode electrode AE and the second connection electrode CNE2 described later.

The anode planarization layer APL may be disposed on the anode auxiliary electrode AAX in a portion overlapping the light emitting area EA. The anode planarization layer APL may be in contact with the anode auxiliary electrode AAX in a portion overlapping the first anode contact hole ACTH1.

The anode planarization layer APL may planarize a step difference included in the anode auxiliary electrode AAX in the portion overlapping the first anode contact hole ACTH1. In addition, the anode planarization layer APL may protect the anode auxiliary electrode AAX from deposition and patterning phenomena that are repeatedly performed during the process of fabricating the display device 10. Therefore, the display device 10, according to an embodiment, may solve the problem of damage to the anode auxiliary electrode AAX.

For example, when the anode planarization layer APL is not included in the portion overlapping the first anode contact hole ACTH1, the anode electrode AE that is subsequently processed may have a step difference having the same shape as the step difference included in the anode auxiliary electrode AAX.

For example, when the anode electrode AE has a step difference having the same shape as the step difference included in the anode auxiliary electrode AAX, a portion of the anode electrode AE may have a defect of uneven thickness due to the step difference in the process of forming the anode electrode AE that is subsequently processed.

As an example, when the anode electrode AE has a step difference having the same shape as the step difference included in the anode auxiliary electrode AAX, a portion of the light emitting layer EL may have a defect of uneven thickness due to the step difference in the process of forming the light emitting layer EL that is subsequently processed.

Therefore, the display device 10, according to an embodiment, may assist in forming the anode electrode AE to be flat in the portion overlapping the first anode contact hole ACTH1 by including the anode planarization layer APL.

The anode planarization layer APL may include an inorganic insulating material. As an example, the anode planarization layer APL may include at least one of silicon nitride, silicon oxide, and silicon oxynitride.

For example, when the anode planarization layer APL includes an organic material, a defect in reliability due to organic material outgassing of the anode planarization layer APL may be caused during the process of fabricating the display device 10. Therefore, the anode planarization layer APL according to an embodiment might not include the organic material.

The light emitting element ED may be disposed on the bank structure BN. The light emitting element ED may overlap the bank structure BN and the element insulating layer DIL in the third direction DR3. In addition, the light emitting element ED may overlap the first anode contact hole ACTH1 in the third direction DR3.

The display device 10, according to an embodiment, may be applied to a high-resolution electronic device. Therefore, a plurality of light emitting elements ED included in the display device 10 may be required to be disposed within a narrow area while securing an appropriate separation distance. Accordingly, the display device 10, according to an embodiment, may include the plurality of light emitting elements efficiently disposed within the narrow area by forming the light emitting element ED to be disposed on the bank structure BN.

The light emitting element ED may include a first light emitting element ED1 disposed in the first light emitting area EA1, a second light emitting element ED2 disposed in the second light emitting area EA2, and a third light emitting element ED3 disposed in the third light emitting area EA3. The first light emitting element ED1, the second light emitting element ED2, and the third light emitting element ED3 may be spaced apart from each other.

The first light emitting element ED1 may include an anode electrode AE, a first light emitting layer EL1, and a cathode electrode CE, the second light emitting element ED2 may include an anode electrode AE, a second light emitting layer EL2, and a cathode electrode CE, and the third light emitting element ED3 may include an anode electrode AE, a third light emitting layer EL3, and a cathode electrode CE.

The first light emitting element ED1, the second light emitting element ED2, and the third light emitting element ED3 may emit light of different colors. As an example, the first light emitting element ED1 may emit red light, the second light emitting element ED2 may emit green light, and the third light emitting element ED3 may emit blue light. The colors emitted by the first light emitting element ED1, the second light emitting element ED2, and the third light emitting element ED3 may be determined by the first light emitting layer EL1, the second light emitting layer EL2, and the third light emitting layer EL3.

The anode electrode AE may be disposed on the anode planarization layer APL. The anode electrode AE may be exposed in a portion overlapping the light emitting opening OP and may be in contact with the first to third light emitting layers EL1, EL2, and EL3 in a portion overlapping the light emitting opening OP. An edge of the anode electrode AE that does not overlap the light emitting opening OP may be covered by the second element insulating layer DIL2.

The anode electrode AE may have a stacked film structure in which a material layer having a high work function, such as indium tin oxide (ITO), indium zinc oxide (IZO), zinc oxide (ZnO), or indium oxide (In₂O₃) and a reflective material layer such as silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), or a mixture thereof are stacked. As an example, the anode electrode AE may have a multilayer structure of ITO/Mg, ITO/MgF, ITO/Ag, and ITO/Ag/ITO, but is not necessarily limited thereto.

In an embodiment, a second anode contact hole ACTH2 may be disposed in a portion overlapping the non-light emitting area NLA. The second anode contact hole ACTH2 might not overlap the light emitting opening OP, the light emitting area EA, and the first anode contact hole ACTH1. For example, the second anode contact hole ACTH2 may be spaced apart from the first anode contact hole ACTH1.

The second anode contact hole ACTH2 may be formed by removing a portion of the anode planarization layer APL during the process of fabricating the display device 10. The fabricating process will be described later.

In an embodiment, in a portion overlapping the first anode contact hole ACTH1, the anode electrode AE may be spaced apart from the anode auxiliary electrode AAX and be in contact with the anode planarization layer APL.

In an embodiment, in a portion overlapping the second anode contact hole ACTH2, the anode electrode AE may be in contact with the anode auxiliary electrode AAX. In the portion overlapping the second anode contact hole ACTH2, the anode electrode AE may be electrically connected to the anode auxiliary electrode AAX.

As described above, the anode planarization layer APL, according to the embodiment, may include the inorganic insulating material. Accordingly, the anode electrode AE and the anode planarization layer APL may be electrically insulated. Therefore, the display device 10, according to an embodiment, may assist in electrically connecting the anode electrode AE and the anode auxiliary electrode AAX by forming the second anode contact hole ACTH2 penetrating through a portion of the anode planarization layer APL.

In addition, the display device 10, according to an embodiment, may form the anode electrode AE to be flat by forming the second anode contact hole ACTH2 so as not to overlap the light emitting opening OP. Accordingly, the display device 10, according to an embodiment, may stably secure uniformity in the thickness of the anode electrode AE and the light emitting layer EL.

The insulating pattern APP may be disposed on the anode auxiliary electrode AAX in a portion overlapping the non-light emitting area NLA. The insulating pattern APP may be spaced apart from the anode planarization layer APL with the anode electrode AE. For example, the insulating pattern APP and the anode planarization layer APL may be spaced apart from each other with the second anode contact hole ACTH2.

The insulating pattern APP may be formed integrally with the anode planarization layer APL during the process of fabricating the display device 10, and then formed in the shape illustrated after the process of forming the second anode contact hole ACTH2. Therefore, the insulating pattern APP may include the same material as the anode planarization layer APL.

In an embodiment, the anode auxiliary electrode AAX may include a first portion ax1, a second portion ax2, and a third portion ax3 depending on portions in contact therewith. As an example, the first portion ax1 may be a portion in contact with the anode planarization layer APL, the second portion ax2 may be a portion in contact with the insulating pattern APP, and the third portion ax3 may be a portion in contact with the anode electrode AE. The third portion ax3 may be disposed between the first portion ax1 and the second portion ax2.

The second element insulating layer DIL2 may be disposed on the anode electrode AE. The second element insulating layer DIL2 may define the light emitting opening OP and expose the anode electrode AE in a portion overlapping the light emitting opening OP. The second element insulating layer DIL2 may be disposed to surround the light emitting opening OP and cover an edge of the anode electrode AE.

The second element insulating layer DIL2 may be in contact with and cover the anode electrode AE in a portion overlapping the second anode contact hole ACTH2. The second element insulating layer DIL2 may extend from the portion in contact with and covering the anode electrode AE and may be in contact with and cover the insulating pattern APP in a portion overlapping the non-light emitting area NLA.

The second element insulating layer DIL2 may include an inorganic insulating material. As an example, the second element insulating layer DIL2 may include at least one of silicon nitride, silicon oxide, and silicon oxynitride.

The first to third light emitting layers EL1, EL2, and EL3 may be disposed on the anode electrode AE. The first to third light emitting layers EL1, EL2, and EL3 may be disposed in portions overlapping the light emitting area EA and the non-light emitting area NLA. The first to third light emitting layers EL1, EL2, and EL3 may overlap the bank structure BN, the element insulating layer DIL, the anode auxiliary electrode AAX, the anode planarization layer APL, and the insulating pattern APP in the third direction DR3.

The first to third light emitting layers EL1, EL2, and EL3 may be in contact with the anode electrode AE in the portion overlapping the light emitting opening OP and may entirely cover the second element insulating layer DIL2 in the portion overlapping the non-light emitting area NLA. The first to third light emitting layers EL1, EL2, and EL3 may extend therefrom and may be in contact with the insulating pattern APP, the anode auxiliary electrode AAX, and the first element insulating layer DIL1.

Although it is illustrated in the drawing that the first to third light emitting layers EL1, EL2 and EL3 are in contact with the tip of the third bank layer BN3, the present specification is not necessarily limited thereto. Depending on the embodiments, the first to third light emitting layers EL1, EL2, and EL3 might not be in contact with the third bank layer BN3.

The first to third light emitting layers EL1, EL2, and EL3 may be organic light emitting layers including organic materials. The first to third light emitting layers EL1, EL2, and EL3 may include any commonly used materials.

The first light emitting layer EL1, the second light emitting layer EL2, and the third light emitting layer EL3 may emit light of different colors. As an example, the first light emitting layer EL1 may emit red light, the second light emitting layer EL2 may emit green light, and the third light emitting layer EL3 may emit blue light, but the present specification is not necessarily limited thereto.

The first light emitting layer EL1 may be disposed in a portion overlapping the first light emitting area EA1, the second light emitting layer EL2 may be disposed in a portion overlapping the second light emitting area EA2, and the third light emitting layer EL3 may be disposed in a portion overlapping the third light emitting area EA3. The first light emitting layer EL1, the second light emitting layer EL2, and the third light emitting layer EL3 may be spaced apart from each other in the portion overlapping the non-light emitting area NLA.

In the display device 10, according to an embodiment, the first light emitting layer EL1, the second light emitting layer EL2, and the third light emitting layer EL3 spaced apart from each other may be formed without using a separate fine metal mask during the process of fabricating the display device 10, as the third bank layer BN3 includes the tip. The fabricating process will be described later.

The cathode electrode CE may be disposed on the first to third light emitting layers EL1, EL2, and EL3. The cathode electrode CE may be disposed in the portions overlapping the light emitting area EA and the non-light emitting area NLA. The cathode electrode CE may entirely cover the first to third light emitting layers EL1, EL2, and EL3.

The cathode electrode CE may be in contact with the bank structure BN, and thus may be electrically connected to the bank structure BN. For example, the cathode electrode CE may be in contact with the tip of the third bank layer BN3 and/or the first side surface 2c of the second bank layer BN2.

The cathode electrode CE includes a transparent conductive oxide, so that the light generated in the first to third light emitting layers EL1, EL2, and EL3 may be emitted. As an example, the cathode electrode CE may include a material layer having a low work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.). As used herein, a material layer having a low work function may be understood to be any material layer having a work function that is equal to or lower than the work function of any of the materials listed herein by way of example. The cathode electrode CE may further include a transparent metal oxide layer disposed on the material layer having the small work function.

In an embodiment, the cathode electrode CE disposed in a portion overlapping the first light emitting area EA1, the cathode electrode CE disposed in a portion overlapping the second light emitting area EA2, and the cathode electrode CE disposed in a portion overlapping the third light emitting area EA3 may be spaced apart from each other. The cathode electrodes CE may be spaced apart from each other in the first to third light emitting areas EA1, EA2, and EA3, respectively, and may be electrically connected through the bank structure BN. For example, the cathode electrodes CE spaced apart from each other in the first to third light emitting areas EA1, EA2, and EA3, respectively, may be in contact with third bank layers BN3 spaced apart from each other in the first to third light emitting areas EA1, EA2, and EA3, respectively, and may be electrically connected to each other through the second bank layer BN2 and the first bank layer BN1 that are electrically connected to the third bank layer BN3.

In the display device 10, according to an embodiment, as the third bank layer BN3 includes the tip, the cathode electrodes CE spaced apart from each other in the first to third light emitting areas EA1, EA2, and EA3 may be formed without a separate fine metal mask. The fabricating process will be described later.

The element inorganic layer IO may be disposed on the light emitting element ED. The element inorganic layer IO may completely cover the light emitting element ED and may prevent oxygen or moisture from permeating into the light emitting element ED.

The element inorganic layer IO may be spaced apart from the first bank layer BN1 in the third direction DR3.

The element inorganic layer IO may include an inorganic insulating material. As an example, the element inorganic layer IO may include at least one of silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light emitting element ED1 in the first light emitting area EA1, the second element inorganic layer IO2 may be disposed on the second light emitting element ED2 in the second light emitting area EA2, and the third element inorganic layer IO3 may be disposed on the third light emitting element ED3 in the third light emitting area EA3. The first element inorganic layer IO1, the second element inorganic layer IO2, and the third element inorganic layer IO3 may be spaced apart from each other in a portion overlapping the non-light emitting area NLA.

In the drawing, the first element inorganic layer IO1, the second element inorganic layer IO2, and the third element inorganic layer IO3 appear to be formed on the same layer, but in the process of fabricating the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed. The fabricating process will be described later.

The thin film encapsulation layer TFEL may be disposed on the display element layer EML. The thin film encapsulation layer TFEL may include an organic encapsulation layer TFE1 and an inorganic encapsulation layer TFE3.

The organic encapsulation layer TFE1, according to an embodiment, may be disposed on the element inorganic layer IO. As an example, the organic encapsulation layer TFE1 may be entirely in contact with and may cover the first element inorganic layer IO1, the second element inorganic layer IO2, and the third element inorganic layer IO3.

The organic encapsulation layer TFE1 may planarize the step difference formed according to a profile of the lower structure. The organic encapsulation layer TFE1 may fill a spaced portion between the cathode electrode CE and the first bank layer BN1 in the portion overlapping the non-light emitting area NLA.

The organic encapsulation layer TFE1 may include a polymer-based material. As an example, the organic encapsulation layer TFE1 may include an acrylic resin, a silicone resin, an epoxy resin, a silicone acrylic resin, polyimide, and polyethylene.

The inorganic encapsulation layer TFE3 may be disposed on the organic encapsulation layer TFE1. The inorganic encapsulation layer TFE3 may protect the lower structure from permeation of moisture and oxygen. Depending on the embodiment, the inorganic encapsulation layer TFE3 may also be omitted.

The inorganic encapsulation layer TFE3 may include an inorganic insulating material. As an example, the inorganic encapsulation layer TFE3 may include at least one of silicon nitride, silicon oxide, and silicon oxynitride.

Thus, a pixel structure in which each pixel includes three sub-pixels emitting different colors (e.g., red, green, blue), may be arranged with separate light-emitting areas defined by precise bank structures that allow patterning without a fine metal mask. A complex layered stack of transistor circuits, insulating layers, connection electrodes, anode structures with planarization to eliminate step differences, may be used. Further, various light-emitting elements, all engineered to ensure uniform layer thickness and reliable electrical connections, while preventing defects like short circuits and outgassing, may also be used. The structure may be protected by multilayer encapsulation, combining organic and inorganic films, to safeguard the device against moisture and oxygen, supporting the fabrication of high-resolution, reliable, and flexible display panels suitable for advanced electronic devices.

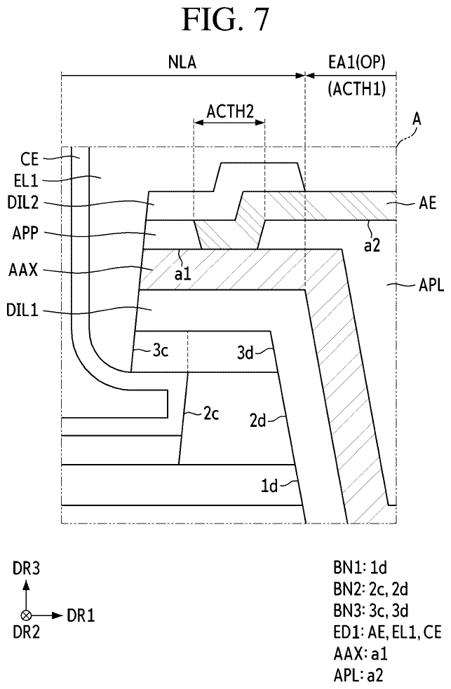

FIG. 7 is an enlarged cross-sectional view of area ‘A’ in FIG. 6.

Referring to FIG. 7 in addition, to FIGS. 1 to 6, the bank structure BN may have an asymmetric structure in a portion facing the first anode contact hole ACTH1 and a portion opposite thereto.

As described above, in the portion facing the first anode contact hole ACTH1, a first side surface 3c of the third bank layer BN3 may protrude further in the first direction DR1 than the first side surface 2c of the second bank layer BN2. For example, the third bank layer BN3 may include a tip that protrudes further in the first direction DR1 than the first side surface 2c of the second bank layer BN2. To the extent that an element is not described in detail with respect to this figure, it may be understood that the element is at least similar to a corresponding element that has been described elsewhere within the present disclosure.

In contrast, in the portion facing the first anode contact hole ACTH1, a side surface 1d of the first bank layer BN1, a second side surface 2d of the second bank layer BN2, and a side surface 3d of the third bank layer BN3 may be disposed on the same line. As used herein, the phrase “disposed on the same line” may be understood to mean that the elements are aligned with one another.

The side surface 1d of the first bank layer BN1, the second side surface 2d of the second bank layer BN2, and the side surface 3d of the third bank layer BN3 may be disposed on the same line and may be removed by the same etching process during the process of fabricating the display device 10. The fabricating process will be described later.

The first element insulating layer DIL1 may be completely in contact with and cover the side surface 1d of the first bank layer BN1, the second side surface 2d of the second bank layer BN2, and the side surface 3d of the third bank layer BN3. In addition, the anode auxiliary electrode AAX may cover the side surface 1d of the first bank layer BN1, the second side surface 2d of the second bank layer BN2, and the side surface 3d of the third bank layer BN3, and may be spaced apart from the side surface 1d of the first bank layer BN1, the second side surface 2d of the second bank layer BN2, and the side surface 3d of the third bank layer BN3 with the first element insulating layer DIL1.

In an embodiment, the anode auxiliary electrode AAX may include a first surface a1 facing the anode electrode AE, and the anode planarization layer APL may include a first surface a2 facing the anode electrode AE.

In an embodiment, the first surface a2 of the anode planarization layer APL may be spaced apart from the first surface a1 of the anode auxiliary electrode AAX in a direction facing one side of the third direction DR3. For example, the first surface a2 of the anode planarization layer APL might not be disposed on the same line as the first surface a1 of the anode auxiliary electrode AAX.

In an embodiment, the anode electrode AE overlapping the second anode contact hole ACTH2 may be in contact with the anode planarization layer APL, the insulating pattern APP, the anode auxiliary electrode AAX, and the second element insulating layer DIL2. For example, an upper surface of the anode electrode AE overlapping the second anode contact hole ACTH2 is in contact with the second element insulating layer DIL2, and a lower surface of the anode electrode AE overlapping the second anode contact hole ACTH2 is in contact with the anode auxiliary electrode AAX. In addition, one side surface of the anode electrode AE overlapping the second anode contact hole ACTH2 in the first direction DR1 may be in contact with the anode planarization layer APL, and the other side surface of the anode electrode AE overlapping the second anode contact hole ACTH2 in the first direction DR1 may be in contact with the insulating pattern APP.

Thus, the bank structure near the first anode contact hole may have an asymmetric profile, with the third bank layer protruding further than lower layers on one side, while being aligned on the other side to enable uniform etching. Additionally, the anode auxiliary electrode, planarization layer, and insulating layers may be arranged and spaced apart from one another to ensure proper electrical connections and insulation around the second anode contact hole, contributing to precise layer structuring and reliable device operation.

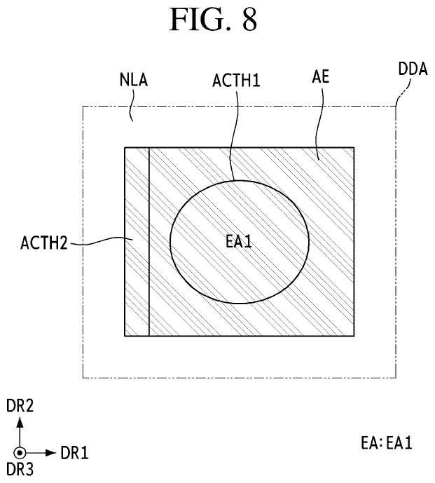

FIG. 8 is an enlarged plan view of an anode electrode overlapping a first anode contact hole and a second anode contact hole in FIG. 6.

Referring to FIG. 8 in addition to FIGS. 1 to 7, in a plan view, the first anode contact hole ACTH1 and the second anode contact hole ACTH2 may be spaced apart from each other. In the plan view, the first anode contact hole ACTH1 may be disposed in a portion overlapping the light emitting area EA, and the second anode contact hole ACTH2 may be disposed in a portion overlapping the non-light emitting area NLA.

In the plan view, the anode electrode AE may completely cover the first anode contact hole ACTH1 and the second anode contact hole ACTH2.

For convenience of explanation, it is illustrated in the drawing that the anode electrode AE is a conductive pattern having a square shape, but the present specification is not necessarily limited thereto. Depending on the embodiment, the anode electrode AE may have various shapes.

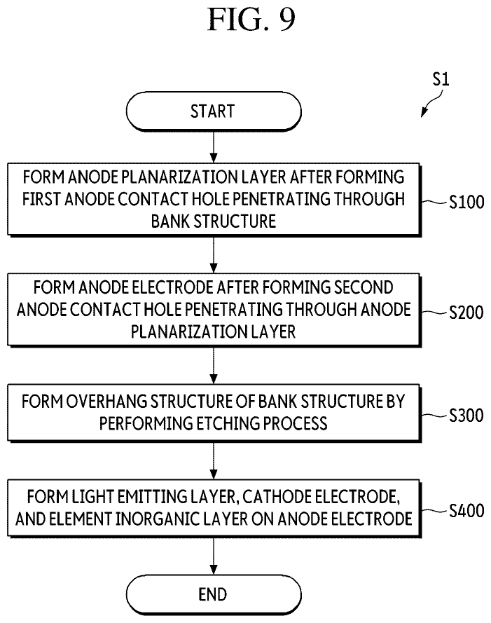

FIG. 9 is a flowchart illustrating a method for fabricating the display element layer of FIG. 5.

Referring to FIG. 9, a method (S1) for fabricating a display element layer EML included in a display device 10, according to an embodiment of the present disclosure, may include a step (S100) of forming an anode planarization layer after forming a first anode contact hole penetrating through a bank structure, a step (S200) of forming an anode electrode after forming a second anode contact hole penetrating through the anode planarization layer, a step (S300) of forming an overhang structure of the bank structure by performing an etching process, and a step (S400) of forming a light emitting layer, a cathode electrode, and an element inorganic layer on the anode electrode.

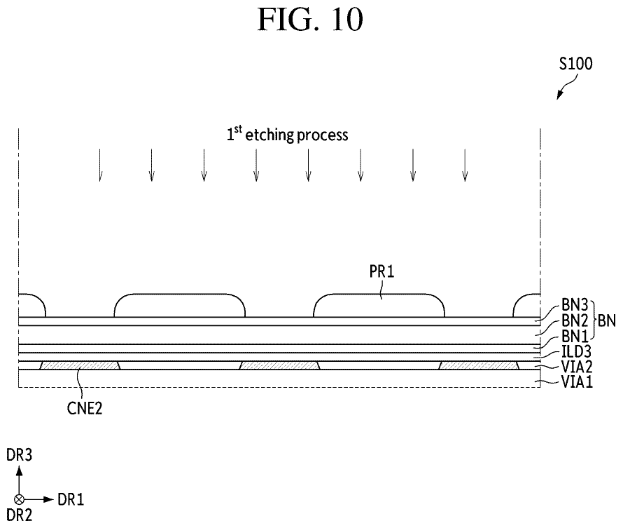

FIGS. 10 to 13 are cross-sectional views for describing step S100 of FIG. 9.

A step (S100) of forming an anode planarization layer after forming a first anode contact hole penetrating through a bank structure will be described with reference to FIGS. 10 to 13 in addition to FIGS. 1 to 9.

First, a plurality of second connection electrodes CNE2 may be formed on a first via layer VIA1, and a second via layer VIA2, a third insulating layer ILD3, and a bank structure BN are entirely formed. The bank structure BN may include a first bank layer BN1, a second bank layer BN2, and a third bank layer BN3 that are sequentially stacked.

In the present process, the second bank layer BN2 and the third bank layer BN3 may include different materials from one another. As an example, the third bank layer BN3 may include a material having higher etching resistance than the second bank layer BN2. To the extent that an element is not described in detail with respect to this figure, it may be understood that the element is at least similar to a corresponding element that has been described elsewhere within the present disclosure.

A thin film transistor layer TFTL including the first via layer VIA1 and the second via layer VIA2 may be disposed on the substrate SUB, and a detailed structure of the thin film transistor layer TFTL may be the same as that illustrated in FIG. 5.

Next, a photoresist PR1 is formed on the third bank layer BN3, and a first etching process is performed. In the present process, a plurality of photoresists PR1 may be formed and may be disposed in portions that do not overlap the second connection electrodes CNE2.

In the present process, the first etching process may be performed as a dry etching process. For example, the dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. In this case, an inductively coupled plasma (ICP) source or a capacitively coupled plasma (CCP) source may be used as a plasma source.

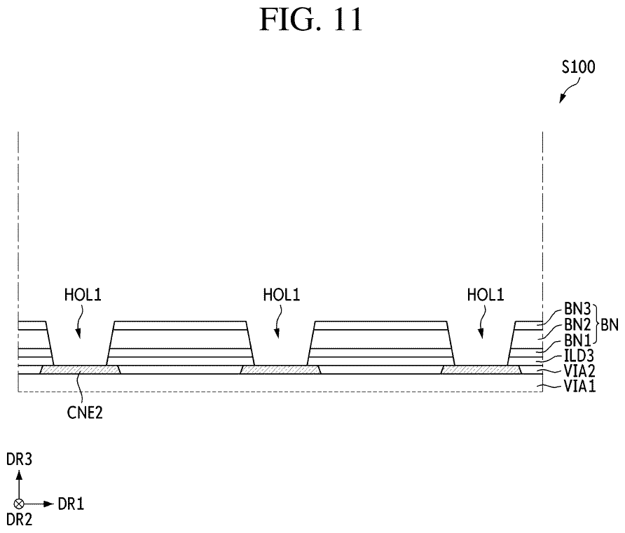

As illustrated in FIG. 11, through the present process, the bank structure BN that does not overlap the photoresists PR1 may be removed all at once, thereby forming holes HOL1. In the present process, in portions overlapping the holes HOL1, the second connection electrodes CNE2 may be exposed, and a side surface of the first bank layer BN1, a side of the second bank layer BN2, and a side surface of the third bank layer BN3 facing the hole HOL1 may be disposed on the same line.

The photoresist PR1 may be removed through an ashing process.

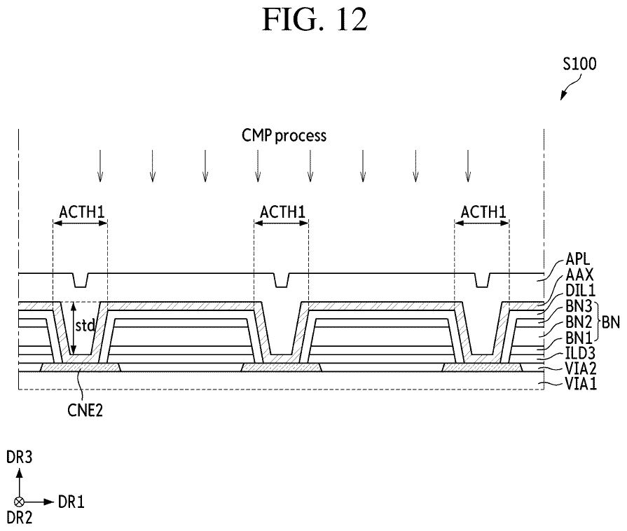

Next, as illustrated in FIG. 12, a first element insulating layer DIL1, an anode auxiliary electrode AAX, and an anode planarization layer APL are formed on the bank structure BN.

In the present process, the process of forming the first element insulating layer DIL1 may be performed through a film forming process (e.g., a deposition process) and a patterning process that form at least one of the above-mentioned inorganic materials.

In the present process, the first element insulating layer DIL1 may have an opening through a patterning process. The first element insulating layer DIL1 may expose the second connection electrode CNE2 in a portion overlapping the opening. In the present specification, the opening defined by the first element insulating layer DIL1 may be named a first anode contact hole ACTH1.

In the present process, the first element insulating layer DIL1 may entirely cover the side surface of the first bank layer BN1, the side surface of the second bank layer BN2, and the side surface of the third bank layer BN3 that face the first anode contact hole ACTH1. The first element insulating layer DIL1 may extend therefrom and cover a side surface of the third insulating layer ILD3 facing the first anode contact hole ACTH1 and a portion of the second connection electrode CNE2.

In the present process, the process of forming the anode auxiliary electrode AAX may be formed through a film forming process (e.g., a sputtering process) that forms at least one of the above-mentioned metal materials.

In the present process, the anode auxiliary electrode AAX may be entirely in contact with and cover the first element insulating layer DIL1 and may extend therefrom to be in contact with and cover the second connection electrode CNE2. As described above, the anode auxiliary electrode AAX may be electrically connected to the second connection electrode CNE2 as including the metal material.

In the present process, the anode auxiliary electrode AAX may be formed with a uniform thickness along the profile of the lower structure. Accordingly, the anode auxiliary electrode AAX may include a step difference std in a portion overlapping the first anode contact hole ACTH1.

In the present process, the process of forming the anode planarization layer APL may be performed through a film forming process (e.g., a sputtering process) that forms at least one of the above-mentioned metal materials.

In the present process, the anode planarization layer APL may be formed with a thickness capable of planarizing the step difference std included in the anode auxiliary electrode AAX in the portion overlapping the first anode contact hole ACTH1.

Next, a chemical mechanical planarization (CMP) process is performed. As an example, the CMP process refers to a process of planarizing a surface with irregularities or curves by polishing the surface using chemical/mechanical elements. Through the present process, a portion of the anode planarization layer APL may be polished and removed.

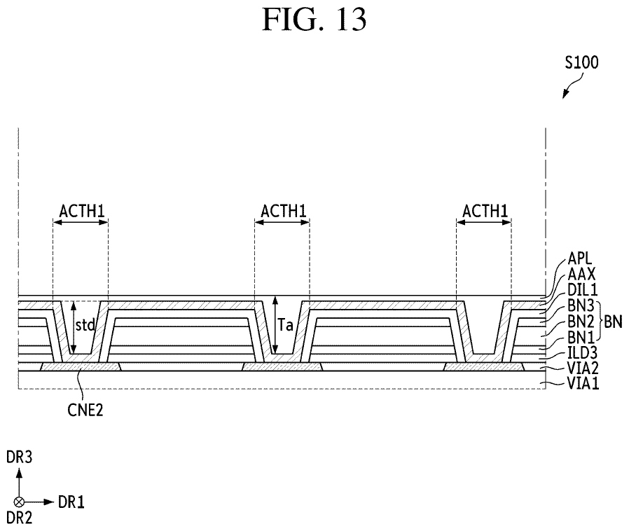

As illustrated in FIG. 13, through the present process, a thickness Ta of the anode planarization layer APL in the portion overlapping the first anode contact hole ACTH1 may have a value greater than a thickness of the step difference std included in the anode auxiliary electrode AAX. Accordingly, the anode planarization layer APL may planarize the step difference std included in the anode auxiliary electrode AAX in the portion overlapping the first anode contact hole ACTH1.

Thus, the fabrication method for the display element layer may involve sequentially forming an anode planarization layer after etching a first anode contact hole through the bank structure, creating a second anode contact hole through the planarization layer, etching the bank structure to form an overhang, and then depositing the light emitting layer, cathode, and encapsulation layers. Detailed steps include forming multiple insulating and conductive layers, precisely etching features, and performing chemical mechanical planarization (CMP) to flatten step differences, ensuring a smooth surface for reliable device performance.

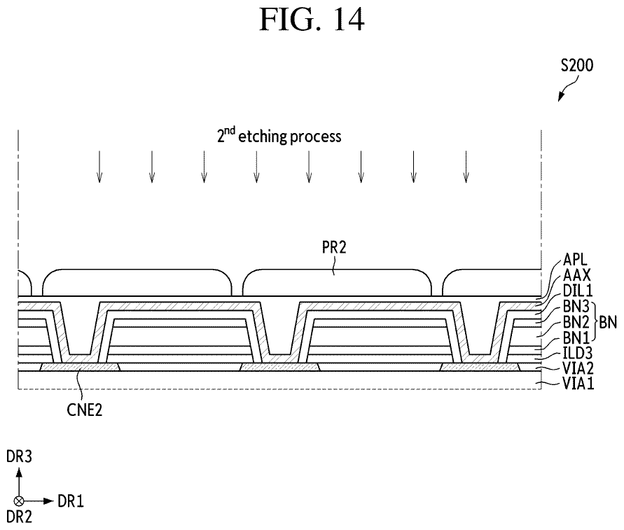

FIGS. 14 to 16 are cross-sectional views for describing step S200 of FIG. 9.

A step (S200) of forming an anode electrode after forming a second anode contact hole penetrating through the anode planarization layer will be described with reference to FIGS. 14 to 16 in addition to FIGS. 1 to 13.

First, a photoresist PR2 is formed on the third bank layer BN3, and a second etching process is performed. In the present process, a plurality of photoresists PR2 may be formed and may expose a portion of the anode planarization layer APL.

In the present process, the second etching process may be performed as a dry etching process. To the extent that an element is not described in detail with respect to this figure, it may be understood that the element is at least similar to a corresponding element that has been described elsewhere within the present disclosure.

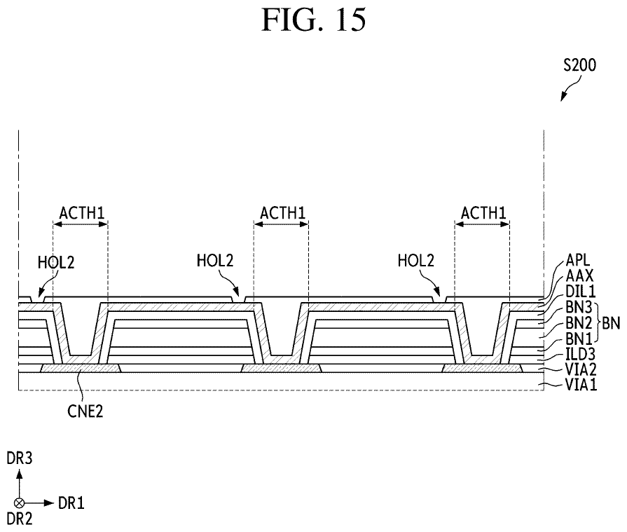

As illustrated in FIG. 15, through the present process, the anode planarization layer APL that does not overlap the photoresists PR2 may be removed, thereby forming holes HOL2. In the present process, the anode auxiliary electrode AAX may be exposed in portions overlapping the holes HOL2. In the present process, the holes HOL2 might not overlap the first anode contact holes ACTH1. The hole HOL2 formed in the present process may be named a second anode contact hole ACTH2 in the present specification.

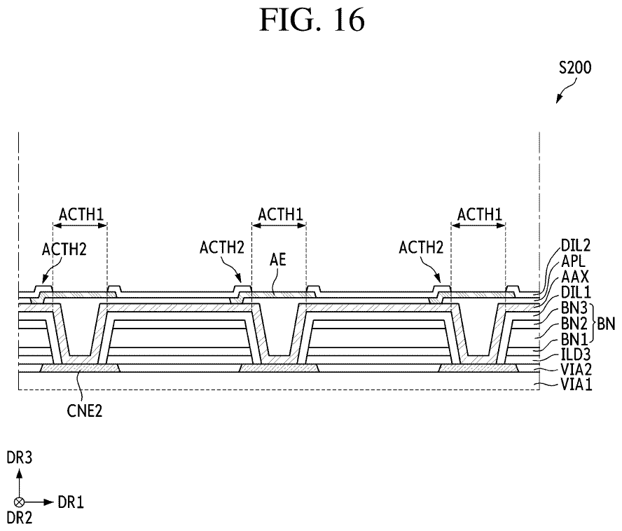

Next, as illustrated in FIG. 16, an anode electrode AE is formed on the anode planarization layer APL.

In the present process, the process of forming the anode electrode AE may be performed through a film forming process (e.g., a sputtering process) and a patterning process that form at least one of the above-mentioned metal materials.

In the present process, the anode electrode AE may be disposed in a portion overlapping the first anode contact hole ACTH1 and the second anode contact hole ACTH2. The anode electrode AE disposed in the portion overlapping the first anode contact hole ACTH1 and the second anode contact hole ACTH2 may be integrally formed.

As described above, as the anode electrode AE is disposed on the anode planarization layer APL in the portion overlapping the first anode contact hole ACTH1, the anode electrode AE may have a relatively flat surface. In addition, as the anode electrode AE is in contact with the anode auxiliary electrode AAX in the portion overlapping the second anode contact hole ACTH2, the anode electrode AE may be electrically connected to the second connection electrode CNE2. To the extent that an element is not described in detail with respect to this figure, it may be understood that the element is at least similar to a corresponding element that has been described elsewhere within the present disclosure.

Next, a second element insulating layer DIL2 that covers an edge of the anode electrode AE is formed.

In the present process, the process of forming the second element insulating layer DIL2 may be performed through a film forming process (e.g., a deposition process) and a patterning process that form at least one of the above-mentioned inorganic materials.

In the present process, the second element insulating layer DIL2 may have an opening through a patterning process. The second element insulating layer DIL2 may expose the anode electrode AE in a portion overlapping the opening. In the present specification, the opening defined by the second element insulating layer DIL2 may be named a light emitting opening OP.

Thus, the process for forming the anode electrode may involve etching the anode planarization layer to create second anode contact holes exposing the underlying anode auxiliary electrode, followed by depositing and patterning the anode electrode so it bridges both first and second contact holes, ensuring electrical connectivity while maintaining a flat surface. Then, a second element insulating layer is formed over the edges of the anode electrode, with patterned openings defining precise regions for light emission.

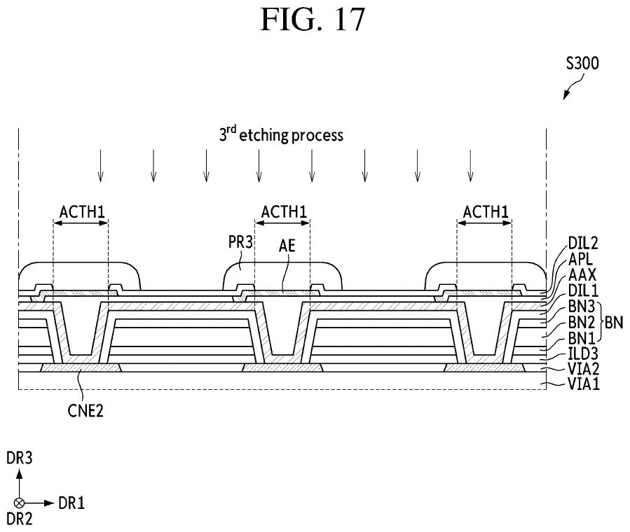

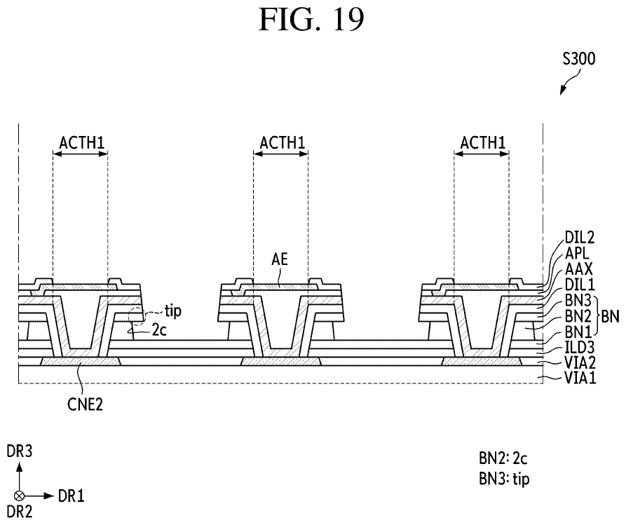

FIGS. 17 to 19 are cross-sectional views for describing step S300 of FIG. 9.

A step (S300) of forming an overhang structure of the bank structure by performing an etching process will be described with reference to FIGS. 17 to 19 in addition to FIGS. 1 to 16.

First, a photoresist PR3 is formed on the second element insulating layer DIL2, and a third etching process is performed. In the present process, a plurality of photoresists PR3 may be formed and may be disposed in portions that overlap the first anode contact holes ACTH1. As an example, the third etching process may be performed through at least one of a dry etching process or a wet etching process.

First, by performing a dry etching process, the second element insulating layer DIL2, the anode planarization layer APL, the anode auxiliary electrode AAX, the first element insulating layer DIL1, and the second bank layer BN2 and the third bank layer BN3 of the bank structure BN that do not overlap the photoresists PR3 are removed.

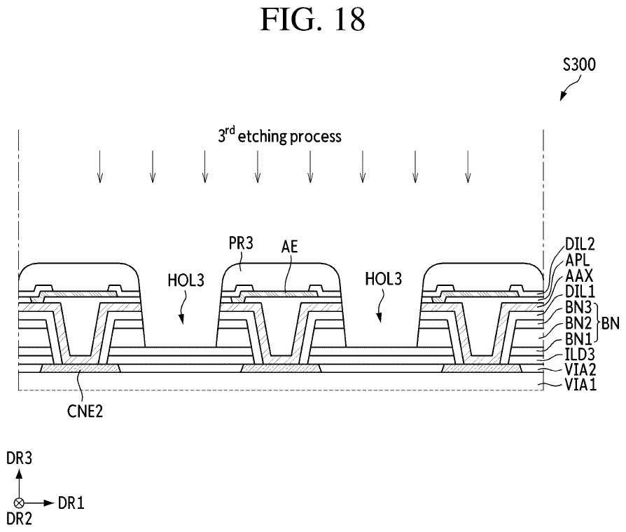

As illustrated in FIG. 18, through the present process, the second element insulating layer DIL2, the anode planarization layer APL, the anode auxiliary electrode AAX, the first element insulating layer DIL1, and the second bank layer BN2 and the third bank layer BN3 of the bank structure BN that do not overlap the photoresists PR3 may be removed all at once. Accordingly, holes HOL3 may be formed in portions that do not overlap the photoresists PR3.

In the present process, the first bank layer BN1 may be exposed in a portion overlapping the hole HOL3, and a side surface of the second element insulating layer DIL2, a side surface of the anode planarization layer APL, a side surface of the anode auxiliary electrode AAX, a side surface of the first element insulating layer DIL1, a side surface of the second bank layer BN2, and a side surface of the third bank layer BN3 that face the hole HOL3 may be disposed on the same line.

Secondly, a tip of the third bank layer BN3 may be formed by performing a wet etching process. For example, the wet etching process may be performed using liquid chemical solutions such as diluted hydrofluoric acid solution, nitric acid solution, tetramethylammonium hydroxide solution, potassium hydroxide solution, etc.

In the present process, the second bank layer BN2 may have a higher etching rate than the third bank layer BN3, the first element insulating layer DIL1, the anode auxiliary electrode AAX, the anode planarization layer APL, and the second element insulating layer DIL2. Therefore, in the present process, the side surface of the second bank layer BN2 facing the hole HOL3 may be depressed in a direction toward the first anode contact hole ACTH1. Therefore, the third bank layer BN3 may include a tip that protrudes further in the first direction DR1 than the first side surface 2c of the second bank layer BN2.

In this way, a bank structure BN having an overhang structure may be formed.

The photoresist PR3 may be removed through an ashing process.

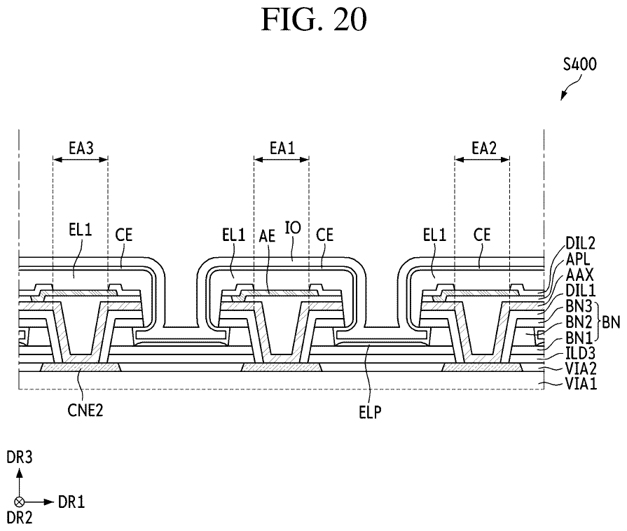

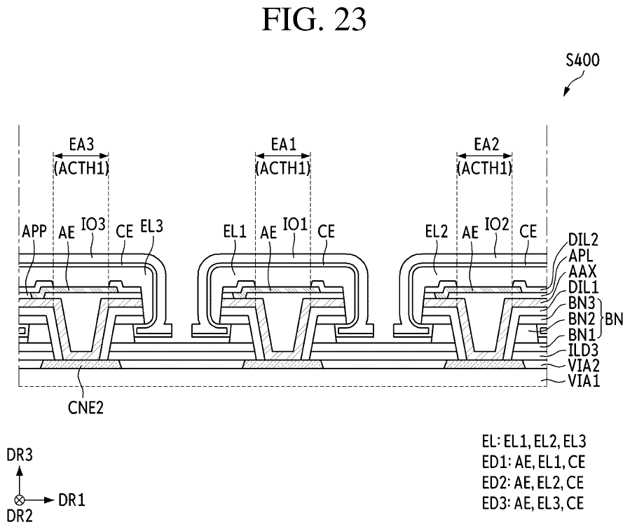

FIGS. 20 to 23 are cross-sectional views for describing step S400 of FIG. 9.

A step (S400) of forming a light emitting element, a cathode electrode, and an element inorganic layer on the anode electrode will be described with reference to FIGS. 20 to 23 in addition to FIGS. 1 to 19.

Next, a first light emitting layer EL1 and a cathode electrode are deposited on the anode electrode AE.

In the present process, the process of forming the first light emitting layer EL1 may be performed through a thermal deposition process. In the present process, the material forming the first light emitting layer EL1 may be formed not only on the anode electrode AE overlapping the first light emitting area EA1, but may also be disposed on the anode electrodes AE disposed in portions overlapping the second light emitting area EA2 and the third light emitting area EA3. The first light emitting layers EL1 disposed in portions overlapping the first to third light emitting areas EA1, EA2, and EA3 may be spaced apart from each other.

In addition, the material forming the first light emitting layer EL1 may also be formed on the first bank layer BN1. The material forming the first light emitting layer EL1 disposed on the anode electrode AE and the material forming the first light emitting layer EL1 disposed on the first bank layer BN1 may be spaced apart from each other. The material forming the first light emitting layer EL1 disposed on the first bank layer BN1 may be named an organic pattern ELP.

In the present process, the process of forming the cathode electrode CE may be performed through a thermal deposition process or a sputtering process. The process of forming the cathode electrode CE may have higher step coverage than the process of forming the first light emitting layer EL1. Therefore, the cathode electrode CE may entirely cover the first light emitting layer EL1.

In the present process, the material forming the cathode electrode CE may be formed not only on the first light emitting layer EL1 overlapping the first light emitting area EA1, but may also be disposed on the first light emitting layer EL1 disposed in portions overlapping the second light emitting area EA2 and the third light emitting area EA3. In addition, the material forming the cathode electrode CE may be formed not only on the first light emitting layer EL1, but also on the organic pattern ELP.

It is illustrated in the drawings that the material forming the cathode electrode CE disposed on the first light emitting layer EL1 and the cathode electrode CE disposed on the organic pattern ELP are integrally formed, but the present specification is not necessarily limited thereto. Depending on the embodiment, the material forming the cathode electrode CE disposed on the first light emitting layer EL1 and the cathode electrode CE disposed on the organic pattern ELP may also be spaced apart from each other.

In the present process, the cathode electrode CE may be in contact with the third bank layer BN3 and/or the second bank layer BN2. To the extent that an element is not described in detail with respect to this figure, it may be understood that the element is at least similar to a corresponding element that has been described elsewhere within the present disclosure.

Next, an element inorganic layer IO is formed on the cathode electrode CE. In the present process, the process of forming the element inorganic layer IO may be performed through a deposition process using any one of the above-mentioned inorganic materials.

The element inorganic layer IO may be disposed in portions overlapping the first light emitting area EA1, the second light emitting area EA2, and the third light emitting area EA3. The element inorganic layer IO may entirely cover the cathode electrode CE.

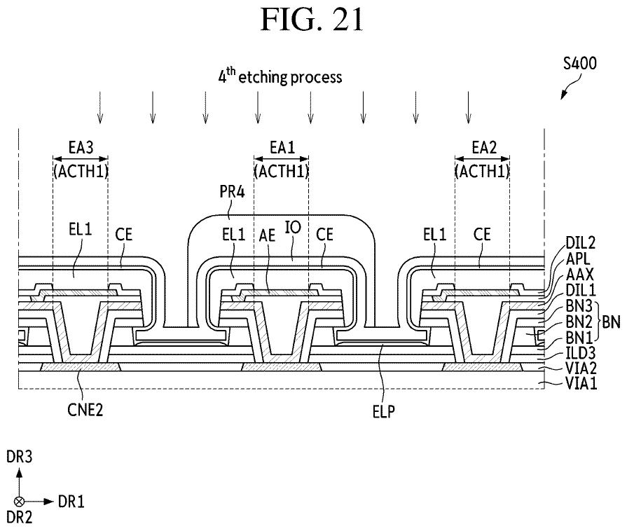

Next, as illustrated in FIG. 21, a photoresist PR4 is formed in a portion overlapping the first light emitting area EA1 and a periphery of the first light emitting area EA1, and a fourth etching process is performed using the photoresist PR4 as a mask. As an example, in the fourth etching process, a dry etching process and a wet etching process may be alternately performed.

In the present process, the material forming the first light emitting layer EL1, the material forming the cathode electrode CE, and the material forming the organic pattern ELP and the element inorganic layer IO that do not overlap the photoresist PR4 may be removed all at once.

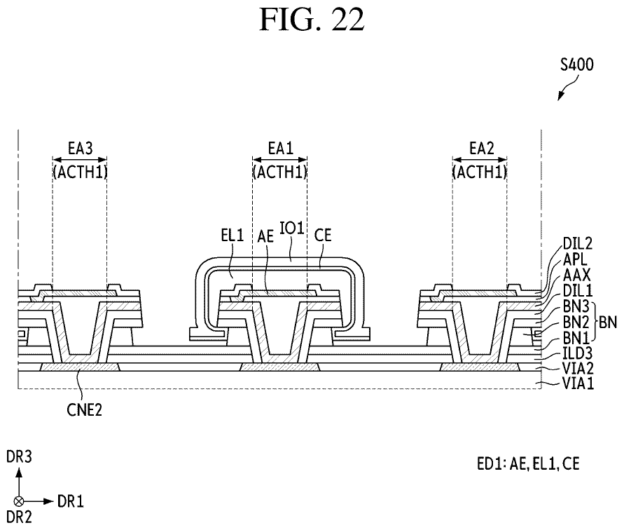

Accordingly, as illustrated in FIG. 22, the element inorganic layer IO may be formed in the form of a first element inorganic layer IO1, and the anode electrode AE overlapping the second light emitting area EA2 and the anode electrode AE overlapping the third light emitting area EA3 may be exposed again.

In this way, the first light emitting element ED1 and the first element inorganic layer IO1 disposed in the portion overlapping the first light emitting area EA1 may be formed.

In the present process, the first element inorganic layer IO1 may be spaced apart from the first bank layer BN1 in the third direction DR3. This may be caused by the organic pattern ELP being temporarily formed between the first element inorganic layer IO1 and the first bank layer BN1 and then removed.

For example, it may be seen in the display device 10, according to an embodiment, that the material forming the light emitting layer EL is formed through the deposition process and the patterning process without a separate fine metal mask through the structure in which the first element inorganic layer IO1 is spaced apart from the first bank layer BN1 in the third direction DR3.

Next, a second light emitting layer EL2, a cathode electrode CE, and an element inorganic layer IO are formed on the anode electrode AE overlapping the second light emitting area EA2 by repeating the above-described processes. Through the present process, the second light emitting element ED2 and the second element inorganic layer IO2 overlapping the second light emitting area EA2 may be formed.

A third light emitting layer EL3, a cathode electrode CE, and an element inorganic layer IO are formed on the anode electrode AE overlapping the third light emitting area EA3 by repeating the above-described processes again. Through the present process, the third light emitting element ED3 and the third element inorganic layer IO3 overlapping the third light emitting area EA3 may be formed.

As a result, the display element layer EML illustrated in FIG. 5 may be formed.

Referring again to FIGS. 1 to 23, the display device 10, according to an embodiment, may form the first light emitting layer EL1, the second light emitting layer EL2, and the third light emitting layer EL3 spaced apart from each other in the portions overlapping the first to third light emitting areas EA1, EA2, and EA3, without the separate fine metal mask, as the third bank layer BN3 includes the tip. Accordingly, the display device 10, according to an embodiment, may have ease of fabrication.

In addition, in the display device 10, according to an embodiment, the contact area of the anode electrode AE and the light emitting area EA may be integrated by forming the first anode contact hole ACTH1 so as to overlap the light emitting area EA without forming the first anode contact hole ACTH1 in a separate space. Therefore, in the display device 10, according to an embodiment, a plurality of light emitting areas EA may be efficiently disposed within a narrow area.

In addition, as the display device 10, according to an embodiment, includes the anode planarization layer APL in the portion overlapping the first anode contact hole ACTH1, the step difference included in the anode auxiliary electrode AAX may be planarized. Accordingly, the display device 10, according to an embodiment, may be formed so that the anode electrode AE has a flat surface in a portion overlapping the light emitting area EA.

In addition, as the anode electrode AE is connected to the anode auxiliary electrode AAX in the portion overlapping the second anode contact hole ACTH2, the display device 10, according to an embodiment, may solve a contact defect of the anode electrode AE.

In addition, in the display device 10, according to an embodiment, the anode electrode AE may have a flat surface in the portion overlapping the light emitting area EA, by separating the first anode contact hole ACTH1 and the second anode contact hole ACTH2 and forming the second anode contact hole ACTH2 so as not to overlap the light emitting area EA.

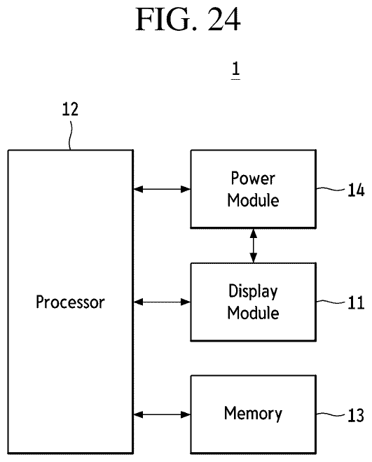

FIG. 24 is a block diagram of an electronic device according to an embodiment.

Referring to FIG. 24 in addition to FIGS. 1 to 23, the display device 10, according to the embodiment, may be applied to various electronic devices 1. The electronic device 1, according to an embodiment, may include the display device 10 described above, and may further include a module or device having additional functions in addition to the display device 10.

The electronic device 1, according to an embodiment, may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 1 other than the display device.

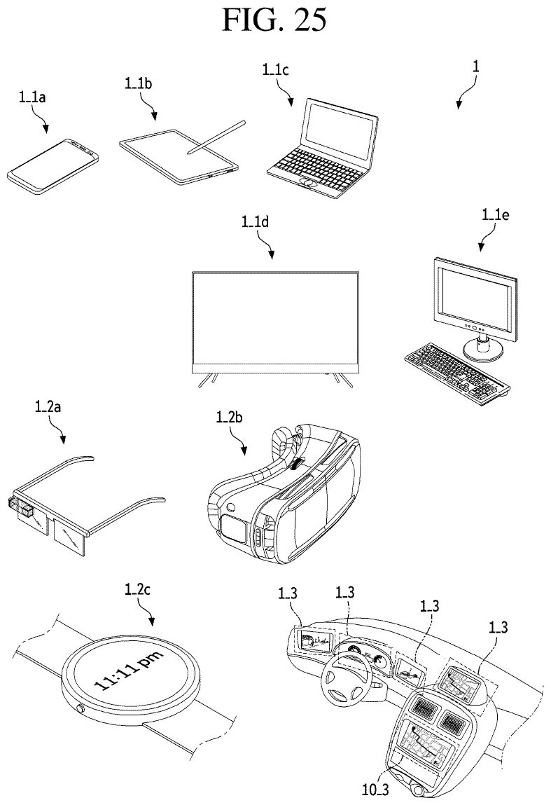

FIG. 25 illustrates schematic diagrams of electronic devices according to various embodiments.

Referring to FIG. 25 in addition to FIGS. 1 to 24, various electronic devices 1 to which the display device 10 according to the embodiments is applied may include not only an image display electronic device such as a smart phone 1_1a, a tablet computer 1_1b, a laptop/notebook computer 1_1c, a TV 1_1d, and a computer monitor 1_1e, but also a wearable electronic device including a display module such as a smart glasses 1_2a, a head mounted display 1_2b, a smart watch 1_2c, and the like, and a vehicle electronic device 1_3 including a display module such as a Center Information Display (CID), a room mirror display, etc., arranged on a vehicle's instrument panel, center fascia, or dashboard.

Embodiments of the disclosure should not necessarily be construed as being limited to the embodiments set forth herein. Rather, these embodiments are provided so that this disclosure will be thorough and complete and will fully convey the concept of the invention to those skilled in the art.

While embodiments of the present disclosure have been particularly shown and described with reference to the drawings, it will be understood by those of ordinary skill in the art that various changes in form and details may be made therein without departing from the spirit or scope of the present disclosure.

What is claimed is:

1. A display device, comprising:
a substrate including a light emitting area and a non-light emitting area, overlapping the light emitting area, and including a connection electrode;
a bank structure disposed on the connection electrode and including an overhang structure;
a first anode contact hole penetrating through the bank structure;
an anode auxiliary electrode overlapping the first anode contact hole and in contact with the connection electrode;
an anode electrode disposed on the anode auxiliary electrode;
an anode planarization layer overlapping the first anode contact hole, disposed between the anode auxiliary electrode and the anode electrode, and including an inorganic material; and
a second anode contact hole overlapping the non-light emitting area, penetrating through a portion of the anode planarization layer, and spaced apart from the first anode contact hole.

2. The display device of claim 1, wherein in a portion overlapping the first anode contact hole, the anode electrode is in contact with the anode planarization layer, and is spaced apart from the anode auxiliary electrode, and
wherein in a portion overlapping the second anode contact hole, the anode electrode is in contact with the anode auxiliary electrode.

3. The display device of claim 2, wherein the anode electrode is connected to the connection electrode through the anode auxiliary electrode.

4. The display device of claim 3, wherein the anode planarization layer planarizes a step difference formed by the anode auxiliary electrode in the portion overlapping the first anode contact hole.

5. The display device of claim 1, further comprising an element insulating layer covering an edge of the anode electrode and defining a light emitting opening,
wherein the first anode contact hole overlaps the light emitting opening, and
wherein the second anode contact hole does not overlap the light emitting opening.

6. The display device of claim 5, further comprising an insulating pattern spaced apart from the anode planarization layer with the second anode contact hole,
wherein the insulating pattern includes a same material as the anode planarization layer.

7. The display device of claim 6, further comprising:
a light emitting layer in contact with the anode electrode in a portion overlapping the light emitting opening; and
a cathode electrode disposed on the light emitting layer and in contact with the bank structure,
wherein the light emitting layer is in contact with the element insulating layer and the insulating pattern.

8. The display device of claim 6, wherein the anode auxiliary electrode includes:
a first portion in contact with the anode planarization layer;
a second portion in contact with the insulating pattern; and
a third portion in contact with the anode electrode,
wherein the third portion is disposed between the first portion and the second portion.

9. The display device of claim 1, wherein the bank structure includes:
a first bank layer;
a second bank layer disposed on the first bank layer; and
a third bank layer having a tip that protrudes further toward the non-light emitting area than a first side surface of the second bank layer,
wherein the anode planarization layer overlapping the first anode contact hole penetrates through the first bank layer, the second bank layer, and the third bank layer.

10. The display device of claim 1, wherein in a plan view, the first anode contact hole and the second anode contact hole are spaced apart from each other, and
wherein in the plan view, the anode electrode entirely covers the first anode contact hole and the second anode contact hole.

11. A method for fabricating a display device, the method comprising:
forming a first anode contact hole penetrating through a bank structure;
forming an anode planarization layer after the forming of the first anode contact hole;
forming a second anode contact hole penetrating through the anode planarization layer;
forming an anode electrode after forming the second anode contact hole;
forming an overhang structure of the bank structure by performing an etching process; and
forming a light emitting layer, a cathode electrode, and an element inorganic layer on the anode electrode.

12. The method of claim 11, wherein in the forming of the anode planarization layer after forming the first anode contact hole penetrating through the bank structure,
a portion of the anode planarization layer is removed by a chemical mechanical planarization (CMP) process.

13. The method of claim 11, wherein in the forming of the anode electrode after forming the second anode contact hole penetrating through the anode planarization layer,
the second anode contact hole is formed by performing a dry etching process.

14. The method of claim 11, wherein in the forming of the overhang structure of the bank structure by performing the etching process,
the bank structure includes a first bank layer, a second bank layer, and a third bank layer, and
the second bank layer and the third bank layer include different metal materials from each other.

15. The method of claim 11, wherein in the forming of the light emitting layer, the cathode electrode, and the element inorganic layer on the anode electrode,
the light emitting layer, the cathode electrode, and the element inorganic layer are formed by a photo pattern process.

16. An electronic device, comprising:
at least one display device including a substrate and a connection electrode, the substrate including a light emitting area and a non-light emitting area, overlapping the light emitting area; and
at least one of a display module, a processor, a memory, and a power module connected to the at least one display device,
wherein the at least one display device includes:
a bank structure disposed on the connection electrode and including an overhang structure;
a first anode contact hole penetrating through the bank structure;
an anode auxiliary electrode overlapping the first anode contact hole and in contact with the connection electrode;
an anode electrode disposed on the anode auxiliary electrode;
an anode planarization layer overlapping the first anode contact hole, disposed between the anode auxiliary electrode and the anode electrode, and including an inorganic material; and
a second anode contact hole overlapping the non-light emitting area, penetrating through a portion of the anode planarization layer, and spaced apart from the first anode contact hole.

17. The electronic device of claim 16, wherein in a portion overlapping the first anode contact hole, the anode electrode is in contact with the anode planarization layer, and is spaced apart from the anode auxiliary electrode, and
wherein in a portion overlapping the second anode contact hole, the anode electrode is in contact with the anode auxiliary electrode.

18. The electronic device of claim 16, further comprising an element insulating layer covering an edge of the anode electrode and defining a light emitting opening,
wherein the first anode contact hole overlaps the light emitting opening, and
wherein the second anode contact hole does not overlap the light emitting opening.

19. The electronic device of claim 18, further comprising an insulating pattern spaced apart from the anode planarization layer by the second anode contact hole,
wherein the insulating pattern includes a same material as the anode planarization layer.

20. The electronic device of claim 19, wherein the anode auxiliary electrode includes:
a first portion in contact with the anode planarization layer;
a second portion in contact with the insulating pattern; and
a third portion in contact with the anode electrode,
wherein the third portion is disposed between the first portion and the second portion.
